(19) United States
(12) Patent Application Publication
(10) Pub. No.: US 2008/0011713 A1
(43) Pub. Date: Jan. 17, 2008

(54) Substrate processing apparatus, substrate processing method and substrate manufacturing method

(75) Inventor: Yoshitake Ito, Ishioka-shi (JP)

Correspondence Address: KANESAKA BERNER AND PARTNERS LLP, 1700 DIAGONAL RD, SUITE 310, ALEXANDRIA, VA, 22314-2848, US

(73) Assignee: Yoshitake ITO, Ishioka-shi (JP)

(21) Appl. No.: 11/645,559

(22) Filed: Dec. 27, 2006

(30) Foreign Application Priority Data
Jul. 14, 2006 (JP) 2006-194805
Sep. 26, 2006 (JP) 2006-260944

(51) Int. Cl. C23F 1/00; C03C 15/00; H01L 21/306

(52) U.S. Cl. 216/41; 156/345.11; 216/42; 216/47; 118/320; 118/52

(57) ABSTRACT

A substrate processing apparatus of the invention has a self-propelled carrying mechanism 15 configured to enable a processing target substrate W to be carried to/from each of liquid processing apparatuses HB, COT and DEV where at least two liquid processing apparatuses W are linearly disposed and to be movable in parallel with an arrangement direction of the liquid processing apparatuses HB, COT and DEV, substrate delivering/receiving mechanism 20 and 21 configured to enable the processing target substrate W to be delivered and received to/from the self-propelled carrying mechanism 15, and a non-self-propelled carrying mechanism 10 configured to enable the processing target substrate to be delivered and received to/from the substrate delivering/receiving mechanisms 20 and 21.

The present disclosure relates to subject matters contained in Japanese Patent Application No. 2006-194805 filed on Jul. 14, 2006 and Japanese Patent Application No. 2006-260944 filed on Sep. 26, 2006, which are expressly incorporated herein by reference in their entireties.

### BACKGROUND OF THE INVENTION

1. Field of the Invention

The present invention relates to a substrate processing apparatus, substrate processing method and substrate manufacturing method.

2. Description of Related Art

It is generally known using a coating/development apparatus using a photoresist solution in manufacturing an electronic material such as, for example, semiconductor wafers and the like. As an example of such technique, there is Japanese Laid-Open Patent Publication No. 2005-229131.

In this technique, non-self-propelled substrate carrying means is disposed in a center portion of the apparatus, and a semiconductor wafer is directly carried by the substrate carrying means to a coating unit, development unit, cooling section and heating section arranged around the substrate carrying means to undergo the processing in the coating unit, development unit, cooling section and heating section.

However, the non-self-propelled substrate carrying means is limited in its carrying to two blocks according an arrangement of the coating unit and development unit disposed on the circumference of the substrate carrying means, and it has been difficult to install more units in the horizontal direction. In recent years, there has been an issue that the substrate carrying means needs to be further added when units that form an antireflective film and the like are provided as a liquid processing apparatus as well as the conventional coating unit and development unit. Such an addition of the substrate carrying means results in a problem of upsizing of the apparatus by an increase in footprint of the apparatus.

Further, since the substrate carrying means directly carries the semiconductor wafer to the coating unit, development unit, cooling section and heating section, there are problems that a waiting time arises and that throughput is not improved, and furthermore, an issue occurs that it is difficult to improve the processing capability of the apparatus. Moreover, the processing time is not the same and differs between the coating unit and development unit, and the cooling section and heating section, a program for carriage control becomes enormous, and a problem also arises that the maintenance time is long due to complication of the control system.

### SUMMARY OF THE INVENTION

According to a principal viewpoint of the invention, a substrate processing apparatus is provided that has a self-propelled carrying mechanism configured to enable a processing target substrate to be carried to/from each of at least two linearly arranged liquid processing apparatuses and to be movable in parallel with an arrangement direction of the liquid processing apparatuses, a substrate delivering/receiving mechanism configured to enable the processing target substrate to be delivered and received to/from the self-propelled carrying mechanism, and a non-self-propelled carrying mechanism configured to enable the processing target substrate to be delivered and received to/from the substrate delivering/receiving mechanism.

According to another principal viewpoint of the invention, a substrate processing apparatus is provided that has a block processing mechanism provided with at least two linearly arranged liquid processing apparatuses, a self-propelled carrying mechanism configured to enable a processing target substrate to be carried to/from each of the liquid processing apparatuses and to be movable in parallel with an arrangement direction of the liquid processing apparatuses, and substrate delivering/receiving mechanisms configured to enable the processing target substrate to be delivered and received to/from the self-propelled carrying mechanism, a block group processing mechanism provided by stacking a plurality of block processing mechanisms, and a non-self-propelled carrying mechanism configured to enable the processing target substrate to be delivered and received to/from each of the substrate delivering/receiving mechanisms of the block group processing mechanism.

Furthermore, according to still another principal viewpoint of the invention, a substrate processing apparatus is provided that has a self-propelled carrying mechanism configured to enable a processing target substrate to be carried to/from each of two liquid processing apparatuses among at least three linearly arranged liquid processing apparatus and to be movable in parallel with an arrangement direction of the liquid processing apparatuses, a substrate delivering/receiving mechanism configured to enable the processing target substrate to be delivered and received to/from the self-propelled carrying mechanism, and a non-self-propelled carrying mechanism configured to enable the processing target substrate to be delivered and received to/from the substrate delivering/receiving mechanism, while further enabling the processing target substrate to be carried to/from a liquid processing apparatus to/from which the processing target substrate is not carried by the self-propelled carrying mechanism.

### BRIEF DESCRIPTION OF THE DRAWINGS

The various features of novelty which characterize the invention are pointed out with particularity in the claims attached to and forming apart of this specification. For a better understanding of the invention, its operating advantages, and specific objects attained by its use, reference should be had to the accompanying drawing and descriptive matter in which there is illustrated and described a preferred embodiment of the invention.

FIG. 1 is a plan view showing an entire configuration in an embodiment of a substrate processing apparatus according to the invention;

FIG. 2 is a schematic perspective view to explain principal part of the liquid processing apparatus of FIG. 1;

FIG. 3 is a schematic cross-sectional view to explain principal part of a substrate delivering/receiving station of FIG. 2;

FIG. 4 is a schematic perspective view to explain principal part of a cassette unit section of FIG. 1;

FIG. 5 is a schematic perspective view to explain principal part of a substrate delivering/receiving section of FIG. 1;

FIG. 6 is a schematic perspective view to explain principal part of an interface unit section of FIG. 1;

FIG. 7 is a schematic perspective view to explain principal part of a heating processing chamber of FIG. 6;

FIG. 8 is a schematic perspective view to explain principal part of a heater of FIG. 1;

FIG. 9 is a schematic plan view to explain principal part of the liquid processing apparatus of FIG. 2;

FIG. 10 is another schematic perspective view to explain principal part of the liquid processing apparatus of FIG. 1;

FIG. 11 is a schematic rear elevational view to explain principal part of the liquid processing apparatus of FIG. 1;

FIG. 12 is a schematic rear elevational view to explain principal part of the heater of FIG. 8;

FIG. 13 is a schematic plan view to explain another embodiment according to the liquid processing apparatus;

FIG. 14 is a schematic plan view to explain another embodiment according to the liquid processing apparatus;

FIG. 15 is a schematic plan view to explain another embodiment according to the liquid processing apparatus;

FIG. 16 is a schematic plan view to explain another embodiment according to the liquid processing apparatus;

FIG. 17 is a schematic plan view to explain another embodiment according to the liquid processing apparatus;

FIG. 18 is a schematic plan view to explain another embodiment according to the liquid processing apparatus;

FIG. 19 is a schematic plan view to explain another embodiment according to the liquid processing apparatus;

FIG. 20 is a schematic plan view to explain another embodiment according to the liquid processing apparatus;

FIG. 21 is a schematic plan view to explain another embodiment according to the liquid processing apparatus;

FIG. 22 is a schematic rear elevational view to explain another embodiment according to the liquid processing apparatus;

FIG. 23 is a schematic perspective view to explain another embodiment of the substrate delivering/receiving station;

FIG. 24 is a schematic rear elevational view to explain another embodiment of the heater;

FIG. 25 is a schematic plan view to explain another embodiment according to the liquid processing apparatus;

FIG. 26 is a schematic cross-sectional view to explain a processing film according to the liquid processing apparatus of FIG. 25;

FIG. 27 is a schematic rear elevational view to explain another embodiment according to the liquid processing apparatus;

FIG. 28 is a schematic rear elevational view to explain another embodiment according to the liquid processing apparatus;

FIG. 29 is a schematic rear elevational view to explain another embodiment according to the liquid processing apparatus;

FIG. 30 is a schematic perspective view to explain another embodiment of the substrate delivering/receiving station and substrate carrying mechanism;

FIG. 31 is a schematic perspective view to explain another embodiment of the substrate delivering/receiving station and substrate carrying mechanism;

FIG. 32 is a schematic perspective view to explain another embodiment according to the liquid processing apparatus;

FIG. 33 is a schematic plan view to explain another embodiment according to the liquid processing apparatus;

FIG. 34 is a schematic plan view to explain another embodiment according to the liquid processing apparatus;

FIG. 35 is a schematic plan view to explain another embodiment according to the liquid processing apparatus;

FIG. 36 is a schematic plan view to explain the liquid processing apparatus according to FIG. 35;

FIG. 37 is a schematic plan view to explain another embodiment according to the liquid processing apparatus;

FIG. 38 is a schematic cross-sectional view to explain principal part of the liquid processing apparatus according to FIG. 37;

FIG. 39 is a schematic plan view to explain another embodiment according to the liquid processing apparatus;

FIG. 40 is a schematic cross-sectional view to explain another embodiment according to the substrate delivering/receiving station;

FIG. 41 is a schematic perspective view to explain another embodiment according to the interface unit;

FIG. 42 is a schematic perspective view to explain another embodiment according to the interface unit;

FIG. 43 is a schematic cross-sectional view to explain another embodiment according to the cassette unit section;

FIG. 44 is a schematic plan view to explain another embodiment of FIG. 37;

FIG. 45 is a schematic plan view to explain another embodiment of FIG. 39;

FIG. 46 is a schematic view to explain another embodiment according to the liquid processing apparatus;

FIG. 47 is a schematic view to explain another embodiment according to the liquid processing apparatus and the heater;

FIG. 48 is a schematic view to explain another embodiment according to the liquid processing apparatus and the heater;

FIG. 49 is a schematic plan view to explain another embodiment according to the liquid processing apparatus and the heater;

FIG. 50 is a schematic cross-sectional view to explain the liquid processing apparatus of FIG. 49;

FIG. 51 is a schematic perspective view to explain the heater of FIG. 49;

FIG. 52 is a schematic view to explain the heater of FIG. 51;

FIG. 53 is a schematic view to explain another embodiment according to the liquid processing apparatus and the heater;

FIG. 54 is a schematic view to explain another embodiment according to FIG. 53;

FIG. 55 is a schematic cross-sectional view to explain another embodiment of the heater; and

FIG. 56 is a schematic cross-sectional view to explain another embodiment of to the heater.

### DESCRIPTION OF THE PREFERRED EMBODIMENTS

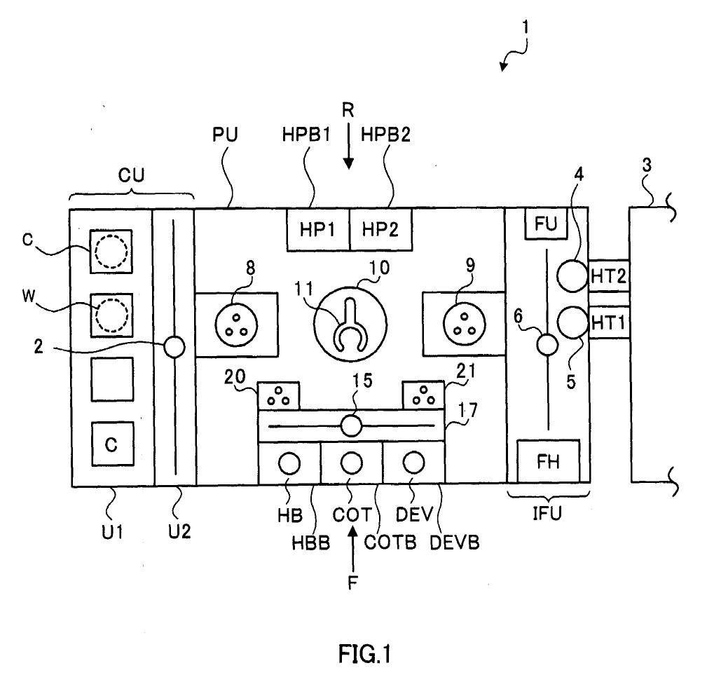

Embodiments of the present invention will specifically be described below with reference to accompanying drawings. FIG. 1 is a schematic plan view showing the entire configuration in an embodiment of a coater and development apparatus as a substrate processing apparatus, for example, as a resist processing apparatus.

The resist processing apparatus 1 is provided at one end with a cassette unit section CU comprised of a cassette mount section U1 configured to enable a plurality of cassettes C each as a storage body capable of storing a plurality of processing target substrates, for example, semiconductor wafers W to be linearly mounted thereon, and a substrate carrying in/out mechanism section U2 in which is provided, for example, a self-propelled substrate carrying in/out mechanism 2 configured to be able to carry a semiconductor wafer W on a sheet basis to/from the cassette C of the cassette mount portion U1, and at the other end with a linearly-formed interface unit section IFU comprised of a delivering portion 4 that delivers the semiconductor wafer W on a sheet basis to another apparatus, for example, an exposure apparatus 3 that performs exposure processing on the semiconductor wafer W via a carrying passage HT2, a receiving portion 5 that receives the semiconductor wafer W on a sheet basis from the exposure apparatus 3 via a carrying passage HT1, and for example, a self-propelled substrate carrying in/out mechanism 6 configured to be able to carry in/out the semiconductor wafer W on a sheet basis. The linearly-formed interface unit section IFU is further provided at one end with a cassette mount portion FU configured to enable at least one cassette C as a storage body capable of storing a plurality of semiconductor wafers W to be mounted thereon, while being provided at the other end with a heating processing chamber FH that performs heating processing on the semiconductor wafer W processed in the exposure apparatus 3, and the substrate carrying in/out mechanism 6 is configured to be able to carry the semiconductor wafer W on a sheet basis to/from the heating processing chamber FH and the cassette C on the cassette mount portion FU.

Further, a process unit section PU is disposed between the cassette unit section CU and interface unit section IFU of the resist processing apparatus 1, while being provided, at one side not in contact with the cassette unit section CU and the interface unit section IFU, with an antireflective film forming apparatus section HBB comprised of a plurality of, for example, four antireflective film forming apparatuses HB which are stacked in the perpendicular direction to be arranged in a block and each of which supplies a predetermined processing liquid to form an antireflective film to the semiconductor wafer W to process, a coater section COTB comprised of a plurality of, for example, four coaters COT which are stacked in the perpendicular direction to be arranged in a block and each of which coats a resist solution onto the semiconductor wafer W, and a development processing apparatus section DEVB comprised of a plurality of, for example, four development processing apparatuses DEV which are stacked in the perpendicular direction to be arranged in a block and each of which develops an exposed resist on the semiconductor wafer W.

The process unit section PU is further provided, at the other side not in contact with the cassette unit section CU and the interface unit section IFU, a heater section HPB1 comprised of a plurality of, for example, four heaters HP1 which are stacked to be arranged in a block and each of which performs processing on the semiconductor wafer W with a predetermined temperature, and a heater section HPB2 comprised of a plurality of, for example, five heaters HP2 which are stacked to be arranged in a block and each of which performs processing on the semiconductor wafer W with a predetermined temperature.

Further, on the cassette unit section CU side of the process unit section PU, a substrate delivering/receiving section 8 is disposed that is configured to be able to carry the semiconductor wafer W on a sheet basis to/from the substrate carrying in/out mechanism 2, while on the interface unit section IFU side of the process unit section PU, a substrate delivering/receiving section 9 is disposed that is configured to be able to carry the semiconductor wafer W on a sheet basis to/from the substrate carrying in/out mechanism 6. In the center portion of the process unit section PU is disposed, for example, a non-self-propelled substrate carrying mechanism 10 that carries the semiconductor wafer W to the substrate delivering/receiving sections 8 and 9 and each of heaters HP1 and HP2 of the heater sections HPB1 and HPB2 using an arm 11. The substrate carrying mechanism 10 is configured to have at least one arm 11 movable in the vertical direction (Z axis), extendable direction (Y axis) and rotation direction (θ axis) (two or more stacked arms may be provided to be driven independently of one another for carrying in and out of the semiconductor wafer W.)

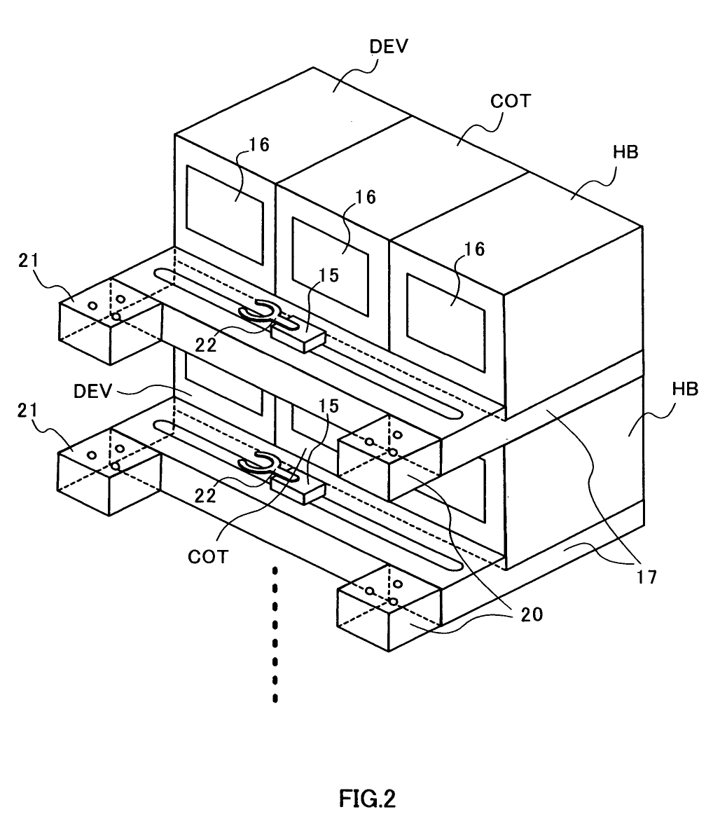

For carrying of the semiconductor wafer W to the liquid processing apparatus by the substrate carrying mechanism 10, as shown in FIG. 2, the antireflective film forming apparatus HB, coater COT and development processing apparatus DEV are linearly disposed and arranged, and a self-propelled carrying mechanism 15 is disposed that is configured to be movable (X axis) in parallel with the arrangement direction. The substrate carrying mechanism 15 has at least one arm 22 configured to be movable in the vertical direction (Z axis), extendable direction (Y axis) and rotation direction (θ axis) (two or more stacked arms may be provided to be driven independently of one another for carrying in and out of the semiconductor wafer W), and is configured to be able to carry the semiconductor wafer W to/from each of the antireflective film forming apparatus HB, coater COT and development processing apparatus DEV via a respective carrying in/out opening 16. In addition, the carrying in/out opening 16 is provided with an opening/closing mechanism not shown, for example, a shutter, and each carrying in/out opening 16 is configured to be openable and closable independently by the shutter.

On the side of a base 17 of the substrate carrying mechanism 15 opposite to the arrangement of the antireflective film forming apparatus HB, coater COT and development processing apparatus DEV, substrate delivering/receiving stations 20 and 21 are disposed that are configured to be able to deliver and receive the semiconductor wafer to/from the substrate carrying mechanism 10. The substrate delivering/receiving stations 20 and 21 enable the substrate carrying mechanism 10 to implement carrying of the semiconductor wafer W to the liquid processing apparatus.

In addition, when the antireflective film forming apparatus HB, coater COT and development processing apparatus DEV are configured in the horizontal direction as a horizontal block, the antireflective film forming apparatus HB, coater COT and development processing apparatus DEV are disposed in the horizontal direction and stacked on the base 17 of the substrate carrying mechanism 15. Assuming thus stacked configuration as one block, four blocks are stacked in the vertical direction. Accordingly, a horizontal block in the horizontal direction of the antireflective film forming apparatus HB, coater COT and development processing apparatus DEV, and a lower horizontal block under the horizontal block in the horizontal direction of the antireflective film forming apparatus HB, coater COT and development processing apparatus DEV are disposed and configured via the base 17 of the substrate carrying mechanism 15 therebetween. By thus disposing, the apparatuses are configured as a block in the horizontal direction and/or as a block in the vertical direction as described previously, and it is thereby possible to reduce the manufacturing time according to manufacturing of the apparatuses, and the like.

Further, a single arm 22 of the substrate carrying mechanism 15 is shown in the figure for convenience, but in consideration of carrying the semiconductor wafer W to/from each of the antireflective film forming apparatus HB, coater COT and development processing apparatus DEV, the mechanism 15 preferably has at least two arms 22 for carrying in and carrying out. Although throughput is an issue, one arm may be provided when one arm is sufficient. When one or more arms 22, for example, two arms 22 are used, the arms may be divided such that one is for carrying of the semiconductor wafer W to the development processing apparatus DEV, and the other one is for carrying of the semiconductor wafer W to the antireflective film forming apparatus HB and coater COT.

This is because the antireflective film forming apparatus HB and coater COT perform processing for coating a resist solution that is different from the liquid processing in the development processing apparatus DEV for developing the resist film. In other words, for example, when one arm 22 carries the semiconductor wafer W to the development processing apparatus DEV, in case a developing solution is adhered to the arm 22, a merit arises that using the other arm 22 prohibits adhesion of the developing solution to the resist film and the like in carrying the semiconductor wafer W to/from the antireflective film forming apparatus HB and coater COT. The number of arms is thus configured to be selected as appropriate. In addition, the substrate carrying mechanism 10 has at least two arms 11 respectively for carrying in and out. A plurality of arms 11 of the substrate carrying mechanism 10 and a plurality of arms 22 of the substrate carrying mechanism 15 are configured to travel in the expansion (Y axis) independently of one another while traveling in the operation of the other axes at the same time.

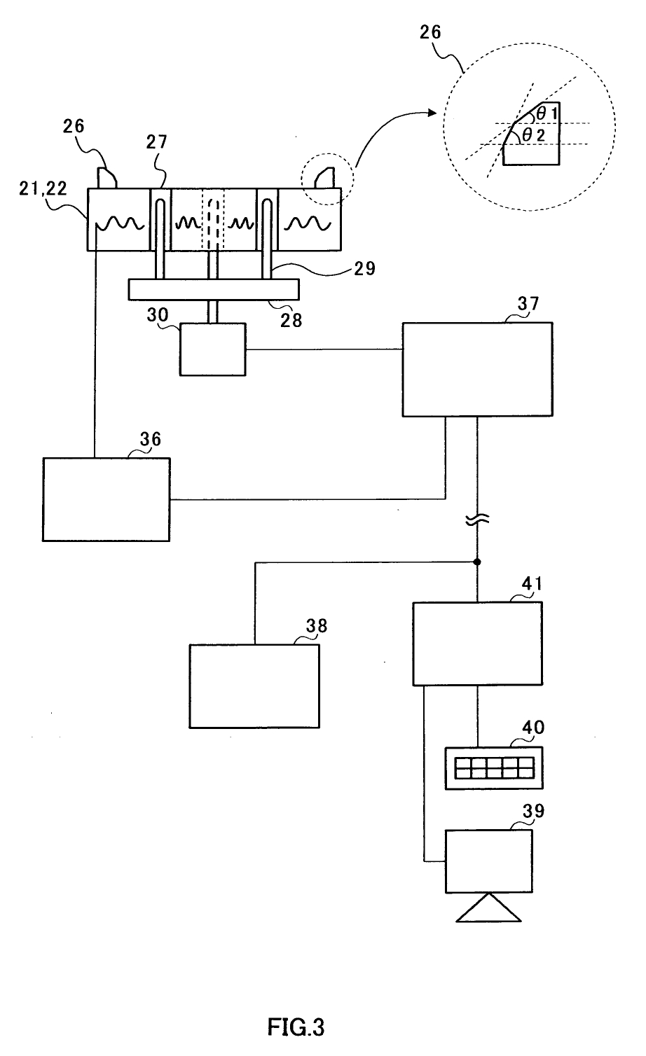

As shown in FIG. 3, each of the substrate delivering/receiving stations 20 and 21 has a plurality of, for example, three positioning mechanisms 26 on a plate 25. The positioning mechanism 26 is provided in the direction toward the center of the plate 25 with a first tilt portion θ1 and second tilt portion θ2 into which an outer edge of the semiconductor wafer W is slid for positioning, and it is configured that the outer edge of the semiconductor wafer W is substantially held by the second tilt portion θ2. In addition, the relationship between an angle of θ1 and an angle of θ2 is that θ1<θ2. Further, a plurality of through holes 27 is provided in the plate 25, and a plurality of support mechanisms, for example, support pins 29 connected to a base 28 are provided through the through holes 27.

The base 28 is configured to be movable up and down by an up/down moving mechanism, for example, an air cylinder 30, and an upper portion of the support pin 29 is configured to be able to protrude from the through hole 27 by the up/down movement of the base 28. Accordingly, after the support pin 29 protrudes from the through hole 27 and is set at a predetermined height position, it is configured that the semiconductor wafer W is carried from the arm 22 of the substrate carrying mechanism 15 or the arm 11 of the substrate carrying mechanism 10, and received in the support pins 29 while being supported from the backside of the semiconductor wafer W in point contact, and that the support pints 29 subsequently move down by the air cylinder 30 so that the semiconductor wafer W slides down substantially to the second tilt portion θ2 of the positioning mechanism 26 to be positioned.

The plate 25 of each of the substrate delivering/receiving stations 20 and 21 has an integrated heating mechanism, for example, a heater 35 to set the semiconductor wafer W placed on the plate 25 at a predetermined temperature, for example, substantially 23° C. as room temperature and the like. The heater 35 is configured to be controlled by a heat control mechanism 36 while measuring the temperature of a temperature sensing mechanism, not shown, for example, a temperature sensor for sensing the temperature of the plate 25. Further, the heat control mechanism 36 is configured to be managed by an upper control mechanism 37.

The upper control mechanism 37 is configured to manage the state of the entire apparatus, but does not directly control a motor of the substrate carrying mechanism 10 and/or the substrate carrying mechanism 15. Such a motor is configured to be controlled by a movement mechanism control apparatus 38 comprised of another CPU (lower). This is because a merit arises of reducing the load on the system since the CPU of the upper control mechanism 37 does not need to directly control. Furthermore, the upper control mechanism 37 is configured to be controllable through communication via a display mechanism, for example, a display 30 as a machine interface for a worker of the apparatus to operate, and an operation mechanism, for example, an operation control mechanism 41 provided with a keyboard 40.

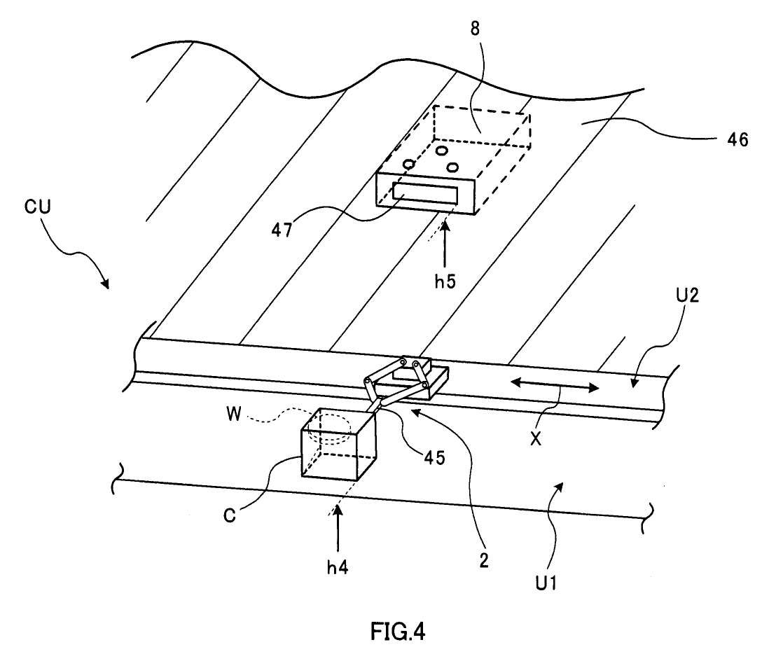

As shown in FIG. 4, the substrate carrying in/out mechanism 2 in the cassette unit section CU is configured to be self-propelled in the X direction (X axis), is provided with an arm 45 configured to be movable in the vertical direction (Z axis), extendable direction (Y axis) and rotation direction (θ axis). Further, a wall 46 is disposed between the cassette unit section CU and process unit section PU, configured to interrupt the atmosphere between the space inside the cassette unit section CU and the space inside the process unit section PU, and provided with an opening 47 of the substrate delivering/receiving section 8, as shown in FIG. 5. The opening 47 is configured to be openable and closable by an opening/closing mechanism not shown, for example, a shutter.

A height position h5 of the opening 47 is set at a position higher than a height position h4 where a cassette C is mounted. Further, the opening 47 is disposed in a position higher than a height position of the arm 45 when the arm 45 of the substrate carrying in/out mechanism 2 travels in the X direction (the longitudinal direction of the cassette unit section CU). The relationship of the height position is that the height position h5 of the opening 47>height position of the arm 45 of the substrate carrying in/out mechanism 2 when the arm 45 travels in the X direction>height position h4 where the cassette C is mounted. By this means, it is possible to prevent the mist and like from the substrate carrying in/out mechanism 2 from entering the process unit section PU side. In addition, above the cassette unit section CU is provided a gas introducing mechanism not shown to flow downward a gas such as clean air toward the cassette unit section CU.

The substrate delivering/receiving section 8 is provided with a plurality of support mechanisms, for example, support pins 50 configured to be movable up and down to deliver and receive the semiconductor wafer W, and to be able to deliver and receive the semiconductor wafer W from/to the substrate carrying in/out mechanism 2 or substrate carrying mechanism 10. Further, in a position above the substrate delivering/receiving portion 8 is disposed a heater 51 that performs heat treatment on the semiconductor wafer W with a first predetermined temperature. Between the heater 51 and substrate delivering/receiving section 8 is disposed a heater 52 that performs heat treatment on the semiconductor wafer W with a second predetermined temperature lower than the first temperature. In a position under the substrate delivering/receiving section 8 is disposed a plurality of temperature adjustment mechanisms 53 to adjust (cool) the temperature of the semiconductor wafer W treated in the heaters 51 and 52 to a predetermined temperature, for example, the temperature substantially the same as the ambient temperature inside the process unit section PU, for example, the temperature of 23° C.

In addition, the substrate carrying mechanism 10 carries the semiconductor wafer W to/from the temperature adjustment mechanisms 53 and heaters 51 and 52, while the substrate carrying in/out mechanism 2 is configured not to be able to access the mechanisms 53 and heaters 51 and 52. Further, openings 54 on the process unit section PU side of the substrate delivering/receiving section 8, temperature adjustment mechanisms 53 and heaters 51 and 52 are configured to be openable and closable by an opening/closing mechanism not shown, for example, a shutter. A filter section not shown is provided above each of the substrate carrying in/out mechanism section U2 of the cassette unit section CU, process unit section PU and interface unit section IFU, and configured to supply the temperature/moisture air with the temperature and moisture of respective set values to each of the units. The temperature/moisture air is configured to be set at a predetermined amount by each exhaust setting mechanism to be collected from an exhaust hole provided under each unit, and it is thus configured that a down-flow of the temperature/moisture air is formed inside each unit. In addition, the pressure inside the interface unit section IFU is set to be lower than the pressure inside the process unit section PU, and set at the apparatus arrangement atmosphere, i.e. pressure higher than the atmosphere pressure inside the clean room, for example, substantially 0.3 Pa.

Further, the pressure of each of the substrate carrying in/out mechanism section U2 of the cassette unit section CU, process unit section PU and interface unit section IFU is set by the exhaust setting mechanism thereof so that the pressure of process unit section PU is set to be higher than both the pressure of the substrate carrying in/out mechanism section U2 of the cassette unit section CU, and the pressure of the interface unit section IFU, and that the pressure inside the exposure apparatus 3 is set to be higher than the pressure of the interface unit section IFU. It is thus configured to prevent unnecessary mist from entering the process unit section PU or exposure apparatus 3 to be a factor having an adverse effect on the processing of the semiconductor wafer W. Further, as compared with the level of oxygen and/or acid gas (NOX, SOX, H₂S, CO₂ and the like), base gas (ammonia, amine and the like), and/or moisture contained in the atmosphere of the cassette unit section CU, the level contained in the atmosphere of the process unit section PU and/or interface unit section IFU is substantially set to be lower than the level of the section CU. This is because of improving the yield of the processing of the semiconductor wafer by reducing effects of the gases particularly in the processing prior or subsequent to exposure.

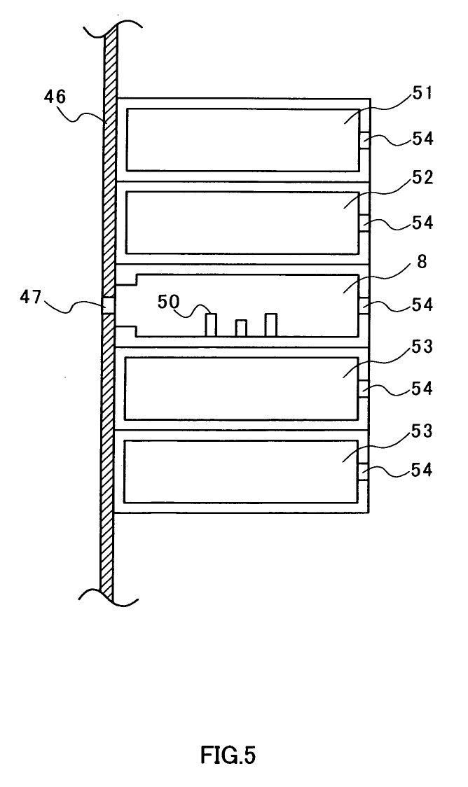

As shown in FIG. 6, the substrate carrying in/out mechanism 6 in the interface unit section IFU is configured to be self-propelled movable in the X direction (X axis), and provided with an arm 55 configured to be movable in the vertical direction (Z axis), extendable direction (Y axis) and rotation direction (θ axis). Further, a wall 56 is provided between the interface unit section IFU and process unit section PU, configured to interrupt the atmosphere between the space inside the interface unit section IFU and the space inside the process unit section PU, and provided with an opening 57 of the substrate delivering/receiving section 9. The opening 57 is configured to be openable and closable by an opening/closing mechanism not shown, for example, a shutter.

A height position h6 of the opening 57 is set at a position lower than a height position h7 of an opening 58 of a heating processing chamber FH. Further, the opening 57 is disposed in a position higher than a height position of the arm 55 when the arm 55 of the substrate carrying in/out mechanism 6 travels in the X direction (the longitudinal direction of the interface unit section IFU). The relationship of the height position is that the height position h6 of the opening 57>height position of the arm 55 of the substrate carrying in/out mechanism 6 when the arm 55 travels in the X direction>height position h7 of the opening 58 of the heating processing chamber FH. It is thus configured to prevent the heat from the heating processing chamber FH and/or mist from the heating processing chamber FH and/or substrate carrying in/out mechanism 2 and like from entering the process unit section PU side. In addition, the height position h6 of the opening 57 is set to substantially the same as the height position h5 of the opening 47, and thus configured to improve the efficiency of carrying by the substrate carrying mechanism 10. In addition, under and above the substrate delivering/receiving section 9 are disposed the heaters or temperature adjustment apparatuses configured to be stacked in the same way as in the substrate delivering/receiving section 8.

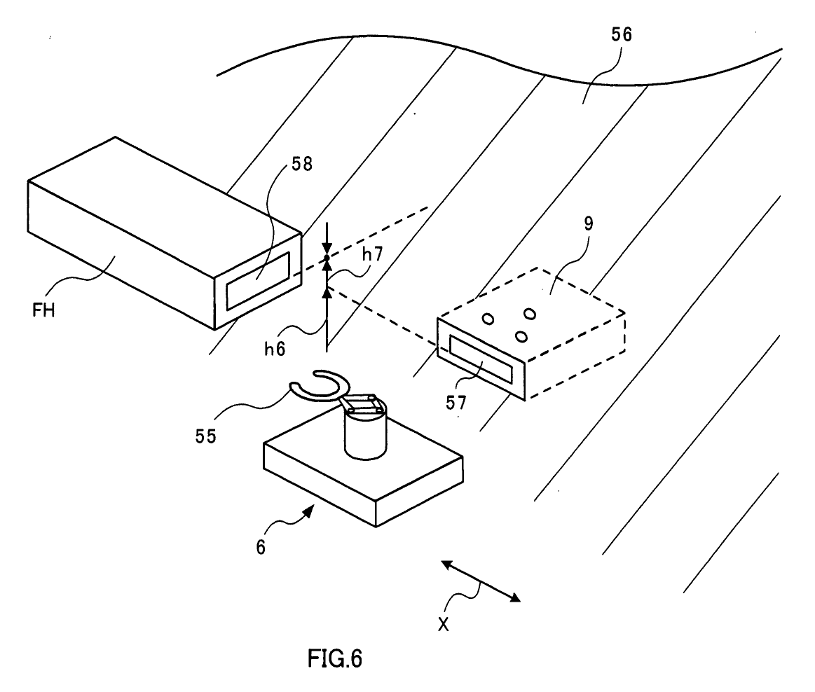

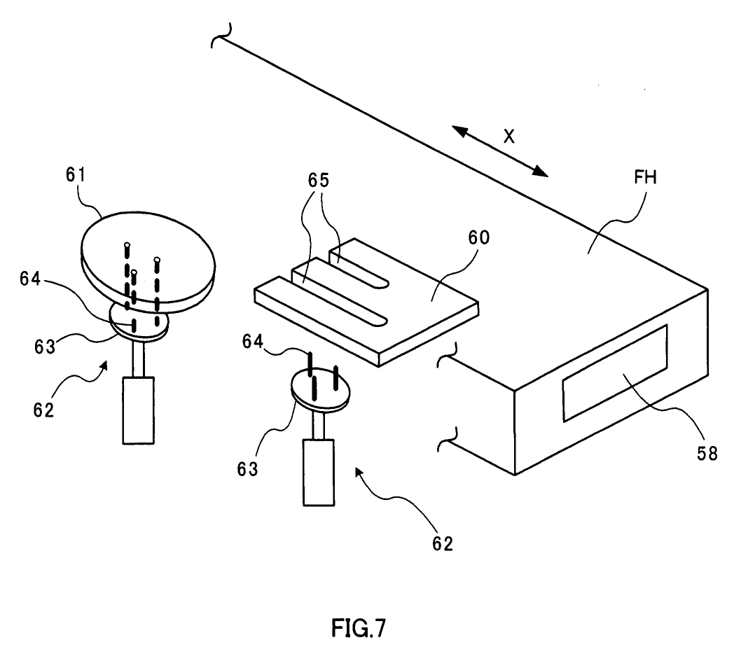

As shown in FIG. 7, the heating processing chamber FH is provided with a rectangular temperature adjustment mechanism 60 that adjusts (cools) the temperature of the semiconductor wafer W to a predetermined temperature, for example, the ambient temperature inside the interface unit section IFU, for example, to 23° C., and a heating mechanism 61 that performs post exposure baking (PEB) on the semiconductor wafer W subjected to the exposure processing in the exposure apparatus 3 at a predetermined temperature. The temperature adjustment mechanism 60 is configured to be movable in the X direction (X axis), and moving up/down mechanisms 62 are provided under the temperature adjustment mechanism 60 in the home position of the mechanism 60 and in a position lower than the heating mechanism 61 to be configured to be able to deliver and receive the semiconductor wafer W to/from the temperature adjustment mechanism 60 and heating mechanism 61, respectively. Each of the moving up/down mechanisms 62 has a plurality of support mechanisms, for example, support pins 64 on a base 63, and is configured to be able to support the semiconductor wafer W from the backside in point contact by the support pins 64.

The temperature adjustment mechanism 60 is further provided with notches 65 not in contact with the support pins 64 of the moving up/down mechanism 62 on the heating mechanism 61 side, and configured to travel to a position above the heating mechanism 61 to be able to deliver and receive the semiconductor wafer W using the support pins 64 of the moving up/down mechanism 62 on the heating mechanism 61 side. In addition, the opening 58 is provided in the X direction (the longitudinal direction of the heating processing chamber FH), and is configured to be openable and closable by an opening/closing mechanism not shown, for example, a shutter. The moving up/down mechanism 62 on the temperature adjustment mechanism 60 side is configured to be able to deliver and receive the semiconductor wafer W to/from the arm 55 of the substrate carrying in/out mechanism 6, as well as delivering and receiving the wafer W to/from the temperature adjustment mechanism 60.

As shown in FIG. 8, each of the heaters HP1 and HP2 of the heater sections HPB1 and HPB2 is provided with a rectangular temperature adjustment mechanism 70 that adjusts (cools) the temperature of the semiconductor wafer W to a predetermined temperature, for example, the ambient temperature inside the process unit section PU, for example, to 23° C., and a heating mechanism 71 that heats and treats the semiconductor wafer W at a predetermined temperature. The temperature adjustment mechanism 70 is configured to be movable in the X direction (X axis), and moving up/down mechanisms not shown are provided under the temperature adjustment mechanism 70 in the home position of the mechanism 70 and in a position lower than the heating mechanism 71 and configured to be able to deliver and receive the semiconductor wafer W to/from the temperature adjustment mechanism 70 and heating mechanism 71, respectively. Each of the moving up/down mechanisms has a plurality of support mechanisms, for example, support pins and is configured to be able to support the semiconductor wafer W from the backside in point contact by the support pins.

The temperature adjustment mechanism 70 is further provided with notches 72 not in contact with the support pins of the moving up/down mechanism on the heating mechanism 71 side, and configured to travel to a position above the heating mechanism 71 to be able to deliver and receive the semiconductor wafer W using the support pins of the moving up/down mechanism 62 on the heating mechanism 71 side. In addition, an opening 73 of each of the heater HP1 and HP2 is provided in the direction perpendicular to the X direction (the longitudinal direction of the heating processing chamber FH), and is configured to be openable and closable by an opening/closing mechanism not shown, for example, a shutter 74. The moving up/down mechanism on the temperature adjustment mechanism 70 side is configured to be able to deliver and receive the semiconductor wafer W to/from the arm 11 of the substrate carrying mechanism 10, as well as delivering and receiving the wafer W to/from the temperature adjustment mechanism 70.

In addition, the heaters HP1 and HP2 are arranged in left-right symmetry. In other words, the temperature adjustment mechanism 70 of the heater HP1 and the temperature adjustment mechanism 70 of the heater HP2 are arranged close to each other. By thus arranging, the distance between openings 73 of the heaters HP1 and HP2 are decreased, and it is thereby possible to shorten the travel distance of the arm 11 of the substrate carrying mechanism 10, and to improve throughput according to carriage. Further, the heating mechanism 71 of the heater HP1 and the heating mechanism 71 of the heater HP2 are arranged in positions spaced apart from each other in the longitudinal direction of the heater, and the arrangement is thus configured to suppress effects by heat conduction and the like on the temperature adjustment apparatus 70 and the like from the heating mechanism 71 of the adjacent heater.

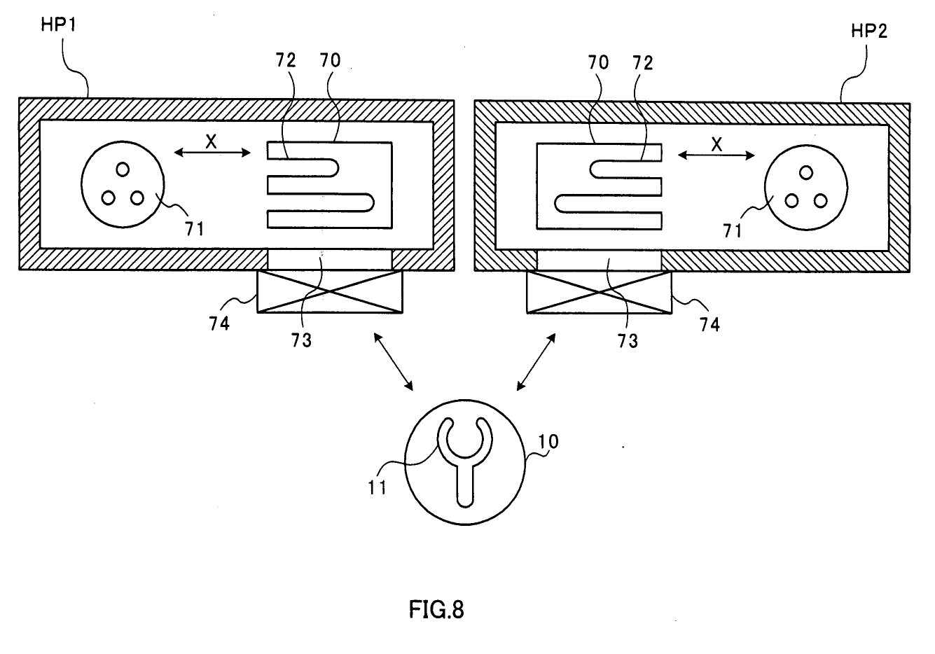

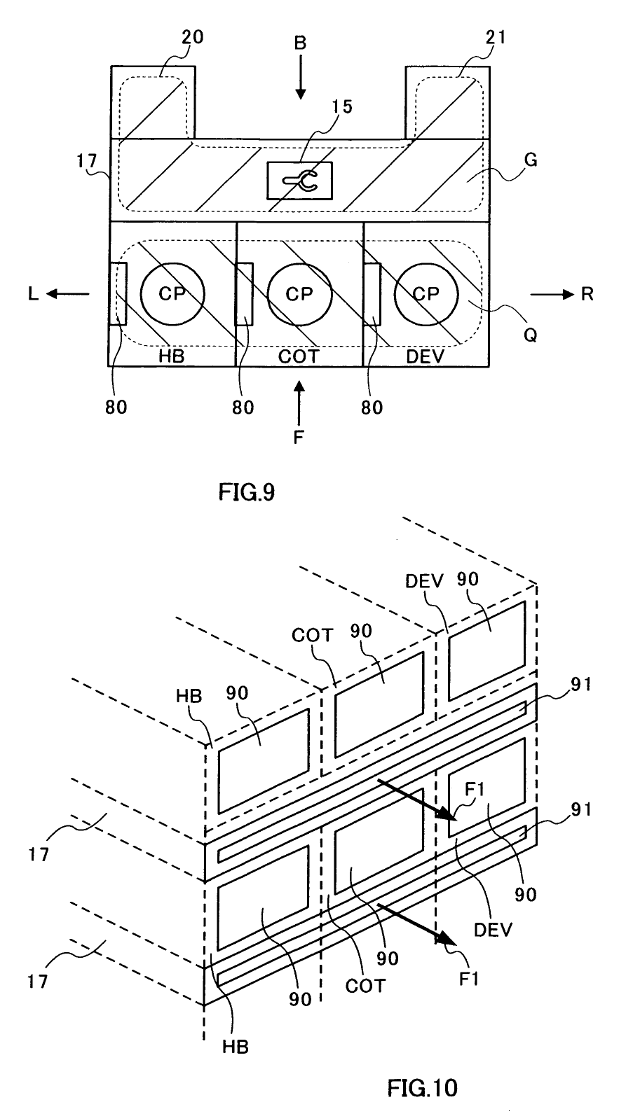

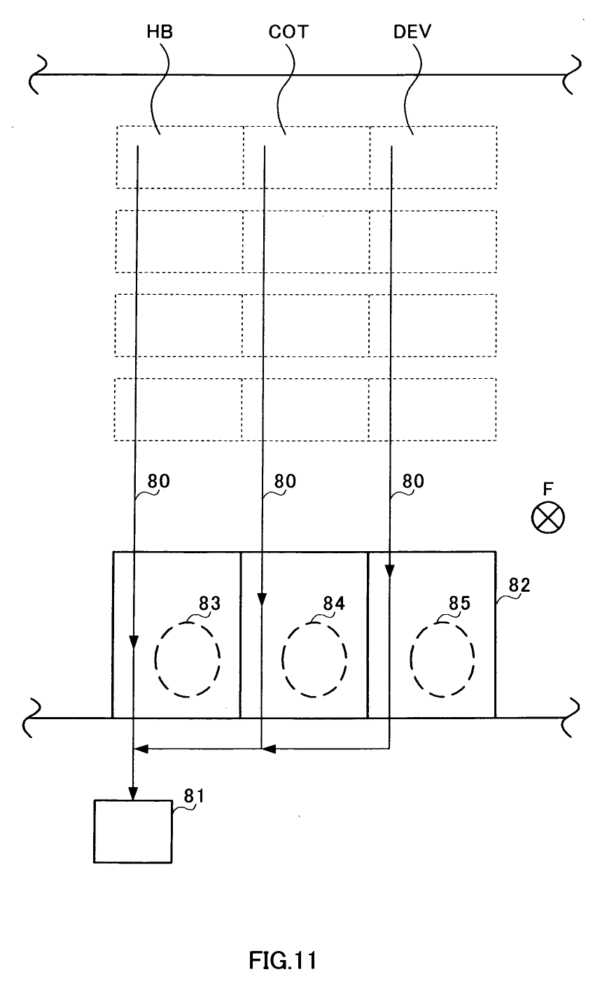

With reference to FIG. 9, described next are configurations of exhaust and the like in the antireflective film forming apparatus HB, coater COT and development processing apparatus DEV. As an exhaust line for each of the antireflective film forming apparatus HB, coater COT and development processing apparatus DEV, each exhaust line 80 is disposed in the direction (L direction in the figure) of the cassette unit section CU side. As shown in FIG. 11, the exhaust line 80 is configured to collectively exhaust gas from each of the liquid processing sections in the vertical direction and to collectively discharge the gas in a position lower than the apparatuses by an exhaust mechanism 81. In addition, the arrow F in the figure indicates the direction viewed from the front of the apparatus. Further, an opening/closing mechanism, for example, a door 82 is provided on the front of the apparatus, and it is configured that storage containers of processing solutions used in the liquid processing apparatuses are placed in regions 83, 84 and 85 in positions not immediately under the exhaust lines 80. For example, it is configured that in the region 83 is placed a storage container of the processing solution used in the antireflective film forming apparatus HB, in the region 84 is placed a storage container of the processing solution used in the coater COT, and that in the region 85 is placed a storage container of the processing solution used in the development processing apparatus DEV.

Heat sources of the substrate carrying mechanism 15, for example, a motor driver and control mechanism and/or power supply and the like of the control mechanism are configured to be disposed in regions of the base 17 of the substrate carrying mechanism 15 and/or substrate delivering/receiving stations 20 and 21. This is because of preventing heat conduction by heat sources and the like of the substrate carrying mechanism 15 from exerting heat effects on the antireflective film forming apparatus HB, coater COT and development processing apparatus DEV that are liquid processing apparatuses. Accordingly, such heat sources are preferably not disposed in a region Q of the antireflective film forming apparatus HB, coater COT and development processing apparatus DEV. However, in the case of no space or the like and the heat sources need to be disposed in the region Q of the antireflective film forming apparatus HB, coater COT and development processing apparatus DEV, it is preferable that the heat sources are not disposed at least immediately under a cup region CP of each of the antireflective film forming apparatus HB, coater COT and development processing apparatus DEV.

For maintenance of the antireflective film forming apparatus HB, coater COT and development processing apparatus DEV, as shown in FIG. 10, an opening/closing mechanism, for example, a door 90 is provided on the front side of the apparatus (F in the figure) for each of the antireflective film forming apparatus HB, coater COT and development processing apparatus DEV, and it is configured that a worker is capable of performing maintenance on each liquid processing apparatus. Further, an opening/closing mechanism, for example, a door 91 is provided in a region of the base 17 of the substrate carrying mechanism 15 on the front side of the apparatus (F in the figure), and a communication port is provided that is configured to be communicable with the control mechanism of the substrate carrying mechanism 15. It is thus configured that maintenance is performed from the front side of the apparatus (F in the figure) of the substrate carrying mechanism 15 using the communication port to improve the efficiency of maintenance.

Further, the heat sources of the substrate carrying mechanism 15, for example, the motor driver and control mechanism and/or power supply and the like of the control mechanism are configured to be drawn from the door 91 in a sliding manner in the F1 direction in the figure. It is thus configured that maintenance of the heat sources and the like of the substrate carrying mechanism 15 can also be performed from the front side of the apparatus (F in the figure) to improve the efficiency of maintenance.

In addition, the arrow B in the figure indicates the direction viewing the apparatus from the backside of the apparatus, while the arrow R in the figure indicates the right direction of the apparatus i.e. the direction of the interface unit section IFU side.

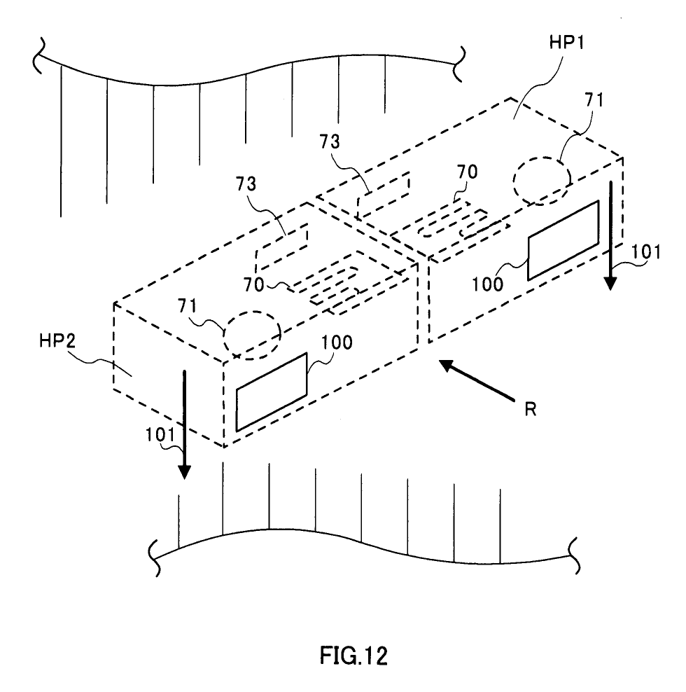

For exhaust and the like according to each of the heaters HP1 and HP2 of the heater sections HPB1 and HPB2, as shown in FIG. 12, an opening/closing mechanism, for example, a door 100 is provided on the heating mechanism 71 side of each of the heater sections HPB1 and HPB2 on the backside of the apparatus (the arrow B in the figure), and is configured to enable a worker to perform maintenance on each heater.

In a region of the door 100 are disposed heat sources in the heaters, for example, a power supply and/or control device and the like so as to suppress heat effects from the heat sources on the temperature adjustment mechanism 70. Further, an outflow of heat to the space of the process unit section PU is suppressed via the opening 73. By this means, the configuration of considering the effects of heat is provided that the heat sources are disposed on the side opposite to the arrangement of openings 73 of the heater sections and on the heating mechanism 71 side without being disposed on the temperature adjustment mechanism 70 side.

Further, an exhaust line 101 of each heater is disposed on the side opposite to the temperature adjustment mechanism 70 of the heating mechanism 71 of each of the heater sections HPB1 and HPB2, and is configured to be able to exhaust collectively for each heater section group arranged in the perpendicular direction. By thus arranging, each exhaust line 101 is spaced a longer distance apart from the opening 73 or temperature adjustment mechanism 70, and the effect of heat from the exhaust line 101 is prevented from acting on the temperature adjustment mechanism 70. Moreover, an outflow of heat to the space of the process unit section PU is suppressed via the opening 73.

Described next is the processing operation of the resist processing apparatus 1 configured as described above. First, a worker or cassette carrying robot places a cassette C storing a plurality of unprocessed semiconductor wafers W in a cassette mount section U1 of the cassette unit section CU. Then, the substrate carrying in/out mechanism 2 of the substrate carrying in/out mechanism section U2 carries the semiconductor wafers W out of the cassette C on a sheet basis, once adjusts the position of the semiconductor wafer W, and delivers the semiconductor wafer W to the substrate delivering/receiving section 8 of the process unit section PU.

Then, the semiconductor wafer W is carried to the heater 51 and/or heater 52 by the arm 11 of the substrate carrying mechanism 10 of the process unit section PU, subjected to hydrophobic treatment in the heaters 51 and/or 52, set at a predetermined temperature, for example, a processing temperature in the coater COT, in the temperature adjustment apparatus 53, and carried to the substrate delivering/receiving station 20 or 21 in one predetermined block among a block group in the vertical direction by the arm 11 of the substrate carrying mechanism 10. The position of the semiconductor wafer W is once adjusted by the positioning mechanism 26. Then, the substrate carrying mechanism 15 carries the semiconductor wafer W to the antireflective film forming apparatus HB in the same block.

In the antireflective film forming apparatus HB, a predetermined processing liquid, for example, a first resist solution is coated on a processing surface of the semiconductor wafer W, the semiconductor wafer W is rotated to form an antireflective film with a predetermined film thickness, for example, a first film thickness, and then, a solvent is supplied to the resist film in the outer edge portion of the rotated semiconductor wafer W from a solvent nozzle to remove an unnecessary resist film. Then, the substrate carrying mechanism 15 carries the semiconductor wafer W from the antireflective film forming apparatus HB to the coater COT inside the same block. In the coater COT, a predetermined processing liquid, for example, a second resist solution different from the first resist solution is coated on the processing surface of the semiconductor wafer W, and the semiconductor wafer W is rotated to form a resist film with a predetermined film thickness, for example, a second film thickness thicker than the first film thickness. Then, a solvent is supplied to the resist film in the outer edge portion of the rotated semiconductor wafer W from a solvent nozzle to remove an unnecessary resist film. Subsequently, the substrate carrying mechanism 15 carries the semiconductor wafer W from the coater COT to the substrate delivering/receiving station 20 or 21. The semiconductor wafer W is once adjusted in position by the positioning mechanism 26.

Then, the semiconductor wafer W is delivered to the temperature adjustment mechanism 70 of predetermined heater HP1 or HP2 of the heater section HPB1 or HPB2 by the arm 11 of the substrate carrying mechanism 10, and subjected to heat treatment at a predetermined temperature in the heating mechanism 71. Subsequently, the semiconductor wafer W is delivered from the heating mechanism 71 to the temperature adjustment mechanism 70, and after the temperature of the semiconductor wafer W reaches a predetermined temperature in the temperature adjustment mechanism 70, carried to the substrate delivering/receiving section 9 by the arm 11 of the substrate carrying mechanism 10. The semiconductor wafer W is delivered to the interface unit section IFU via the substrate delivering/receiving section 9, further delivered to the exposure apparatus 3 from the interface unit section IFU via the substrate carrying in/out mechanism 6, and undergoes exposure processing.

The exposure-processed semiconductor wafer W is delivered to the interface unit section IFU, and then, carried to the heating processing mechanism FH by the substrate carrying in/out mechanism 6. In the heating processing mechanism FH, the semiconductor wafer W is delivered to the temperature adjustment mechanism 60 of the heating processing mechanism FH, and undergoes heat treatment at a predetermined temperature e.g. a first temperature in the heating mechanism 61. Then, the semiconductor wafer W is delivered to the temperature adjustment mechanism 60 from the heating mechanism 61, and after the temperature of the semiconductor wafer W reaches a predetermined temperature in the temperature adjustment mechanism 60, carried to the substrate delivering/receiving section 9 by the substrate carrying in/out mechanism 6. The reason why the heating processing mechanism FH is thus disposed in the interface unit section IFU is because of controlling the time the exposure processing is performed in the exposure apparatus 3 and making the time between the exposure processing in the exposure apparatus 3 and heat treatment constant in each processing target substrate. By this means, the yield of processing target substrates is enhanced.

Then, the semiconductor wafer W is returned to the process unit section PU by the arm 11 of the substrate carrying mechanism 10 via the substrate delivering/receiving section 9. Subsequently, the semiconductor wafer W is further subjected to heat treatment in a selected predetermined heater section disposed in a position above the substrate delivering/receiving section 9 and/or predetermined heaters HP1 and HP2 of the heater sections HPB1 and HPB2. For convenience, an example is described that the semiconductor wafer W is subjected to heat treatment in the predetermined heater HP1 or HP2 of the heater section HPB1 or HPB2. The semiconductor wafer W is delivered to the temperature adjustment mechanism 70 of the predetermined heater HP1 or HP2 of the heater section HPB1 or HPB2, and subjected to heat treatment in the heating mechanism 71 at a predetermined temperature, for example, a second temperature higher than the first temperature of the heat treatment in the heating processing mechanism FH. Subsequently, the semiconductor wafer W is delivered from the heating mechanism 71 to the temperature adjustment mechanism 70, and after the temperature of the semiconductor wafer W reaches a predetermined temperature in the temperature adjustment mechanism 70, carried out by the arm 11 of the substrate carrying mechanism 10. The reason of the second temperature is because the first temperature is only to suppress changes with time in the film of the semiconductor wafer W subjected to the exposure processing in the exposure apparatus 3, and the second temperature is to ensure the film quality resistant to the developing processing.

Subsequently, the semiconductor wafer W is carried to the substrate delivering/receiving station 20 or 21 in one predetermined block among a block group in the vertical direction by the arm 11 of the substrate carrying mechanism 10. The semiconductor wafer W is once adjusted in position by the positioning mechanism 26. Then, the semiconductor wafer W is carried to the development processing apparatus DEV in the same block by the substrate carrying mechanism 15. In addition, in selecting a predetermined block from among a block group in the vertical direction, it is not required to select the same block as the predetermined block among the block group in the vertical direction where the semiconductor wafer W is subjected to the resist processing. Processing throughput is enhanced by selecting a vacant predetermined block from among the block group in the vertical direction as appropriate by the control mechanism to carry the semiconductor wafer W.

Then, in the development processing apparatus DEV, the semiconductor wafer W is supplied on the processing surface with a predetermined processing liquid, for example, a developing solution, rotated to blow a rinse solution and dried. Subsequently, the semiconductor wafer W is carried from the development processing apparatus DEV by the substrate carrying mechanism 15, and delivered to the substrate delivering/receiving station 20 or 21. The semiconductor wafer W is once adjusted in position by the positioning mechanism 26.

Subsequently, the semiconductor wafer W is delivered to the temperature adjustment mechanism 70 of predetermined heater HP1 or HP2 of the heater section HPB1 or HPB2 by the arm 11 of the substrate carrying mechanism 10, and subjected to heat treatment at a predetermined temperature in the heating mechanism 71. Then, the semiconductor wafer W is delivered from the heating mechanism 71 to the temperature adjustment mechanism 70, and after the temperature of the semiconductor wafer W reaches a predetermined temperature in the temperature adjustment mechanism 70, carried to the substrate delivering/receiving section 8 by the arm 11 of the substrate carrying mechanism 10. The semiconductor wafer W is carried in a predetermined cassette C on a sheet basis by the substrate carrying in/out mechanism 2 via the substrate delivering/receiving section 8, and a series of processing is finished.

Described next is another embodiment in a block of the antireflective film forming apparatus HB, coater COT and development processing apparatus DEV as liquid processing apparatuses of this embodiment. In addition, the same components as in the above-mentioned embodiment are assigned the same reference numerals to omit specific descriptions. Naturally, the invention according to this embodiment is capable of being used in a combination with another embodiment, and is not limited to this embodiment.

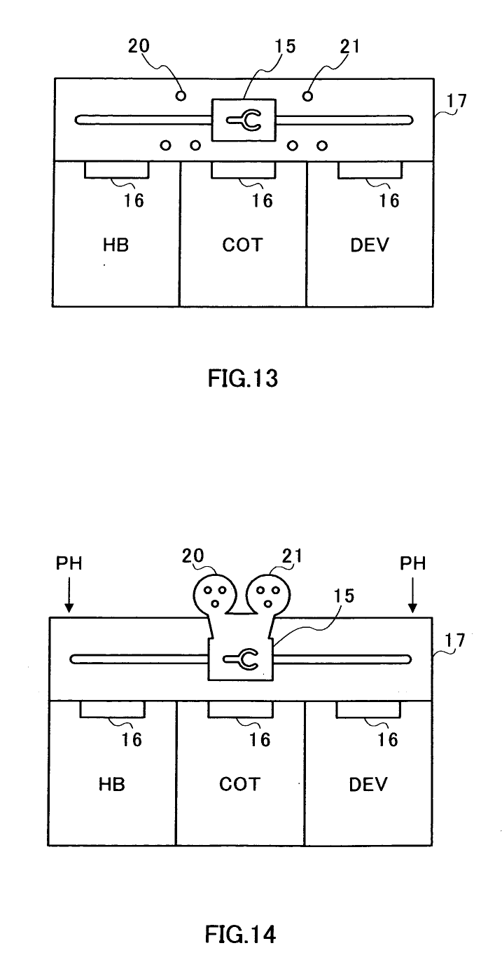

In a block having the antireflective film forming apparatus HB, coater COT and development processing apparatus DEV as the liquid processing apparatuses as described previously, the substrate delivering/receiving stations 20 and 21 are disposed on the side opposite to the antireflective film forming apparatus HB, coater COT and development processing apparatus DEV on the base 17 of the substrate carrying mechanism 15. In contrast thereto, as shown in FIG. 13, the stations 20 and 21 are disposed in a travel region of the substrate carrying mechanism 15 on the base 17 of the substrate carrying mechanism 15 not to contact the substrate carrying mechanism 15. By disposing the substrate delivering/receiving stations 20 and 21 on (or above) the base 17 of the substrate carrying mechanism 15, the region for preventing the down-flow inside the process unit section PU is reduced, and an effect arises of efficiently eliminating the mist and the like inside the process unit section PU from under the apparatus. It is thereby possible to suppress adhesion of the mist and the like to the semiconductor wafer W and to enhance the yield.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

In a block having the antireflective film forming apparatus HB, coater COT and development processing apparatus DEV as the liquid processing apparatuses as described previously, the substrate delivering/receiving stations 20 and 21 are disposed on the side opposite to the antireflective film forming apparatus HB, coater COT and development processing apparatus DEV on the base 17 of the substrate carrying mechanism 15. In contrast thereto, as shown in FIG. 14, the substrate delivering/receiving stations 20 and 21 are disposed in the substrate carrying mechanism 15 itself, and are configured to be movable together with the substrate carrying mechanism 15. Since the stations 20 and 21 are thus arranged, it is possible to make the time constant the substrate carrying mechanism 15 delivers the semiconductor wafer W to the substrate delivering/receiving stations 20 and 21. Further, it is made possible to move carrying positions of the substrate delivering/receiving stations 20 and 21 and the substrate carrying mechanism 10. Therefore, the substrate delivering/receiving stations 20 and 21 are moved to a minimum distance for the substrate carrying mechanism 10 to travel concurrently with a period during which the substrate carrying mechanism 10 travels, and it is thereby possible to improve throughput in deliver and receipt between the substrate delivering/receiving stations 20 and 21 and the substrate carrying mechanism 10, and the like. After the substrate carrying mechanism 15 carries the semiconductor wafer W from the antireflective film forming apparatus HB, coater COT and/or development processing apparatus DEV, the semiconductor wafer W is set at a predetermined temperature in the substrate delivering/receiving stations 20 and 21. Further, when the substrate carrying mechanism 15 carries the semiconductor wafer W to the antireflective film forming apparatus HB, coater COT and/or development processing apparatus DEV, the temperature of the semiconductor wafer W can be controlled in the substrate delivering/receiving stations 20 and 21 immediately before the wafer W is carried in, and it is thus possible to reduce fluctuations in the processing of the semiconductor wafer W.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

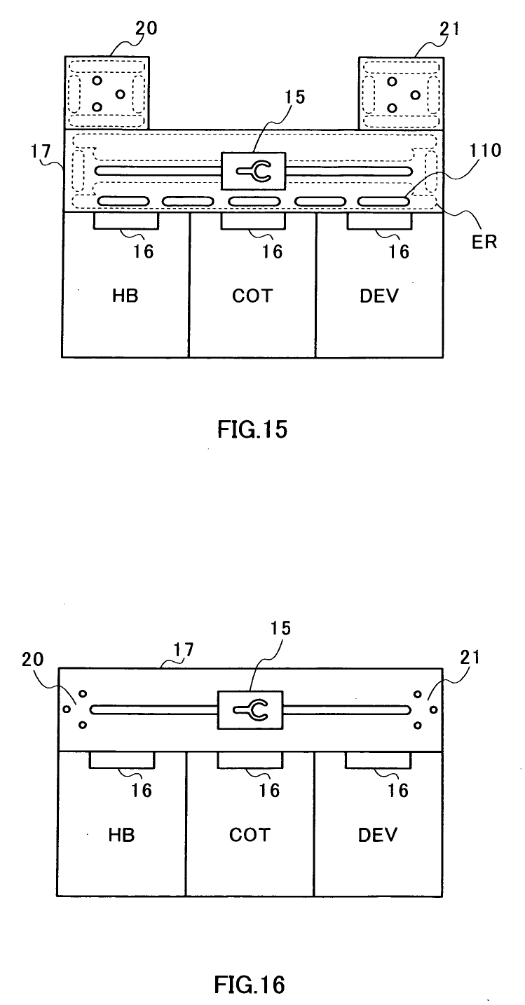

In a block having the antireflective film forming apparatus HB, coater COT and development processing apparatus DEV as the liquid processing apparatuses, as shown in FIG. 15, communication mechanisms, for example, slits, punched holes 110 and the like through which is passed downward the down-flow inside the process unit section PU are provided in each region ER of the base 17 of the substrate carrying mechanism 15 and substrate delivering/receiving stations 20 and 21. By thus providing the communication mechanisms, the region for preventing the down-flow inside the process unit section PU is reduced, and the effect arises of efficiently eliminating the mist and the like inside the process unit section PU from under the apparatus. It is thereby possible to suppress adhesion of the mist and the like to the semiconductor wafer W and to enhance the yield. In addition, the communication mechanisms may be naturally provided also in the substrate carrying mechanism 15 it self, for example, the arm 22.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

In a block having the antireflective film forming apparatus HB, coater COT and development processing apparatus DEV as the liquid processing apparatuses as described previously, the substrate delivering/receiving stations 20 and 21 are disposed on the side opposite to the antireflective film forming apparatus HB, coater COT and development processing apparatus DEV on the base 17 of the substrate carrying mechanism 15. In contrast thereto, as shown in FIG. 16, the stations 20 and 21 are disposed at opposite ends in the longitudinal direction of the base 17 outside the travel region and the substrate carrying mechanism 15 on the base 17 of the substrate carrying mechanism 15 not to contact the substrate carrying mechanism 15. By disposing the substrate delivering/receiving stations 20 and 21 on (or above) the base 17 of the substrate carrying mechanism 15, the region for preventing the down-flow inside the process unit section PU is reduced, and the effect arises of efficiently eliminating the mist and the like inside the process unit section PU from under the apparatus. It is thereby possible to suppress adhesion of the mist and the like to the semiconductor wafer W and to enhance the yield.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

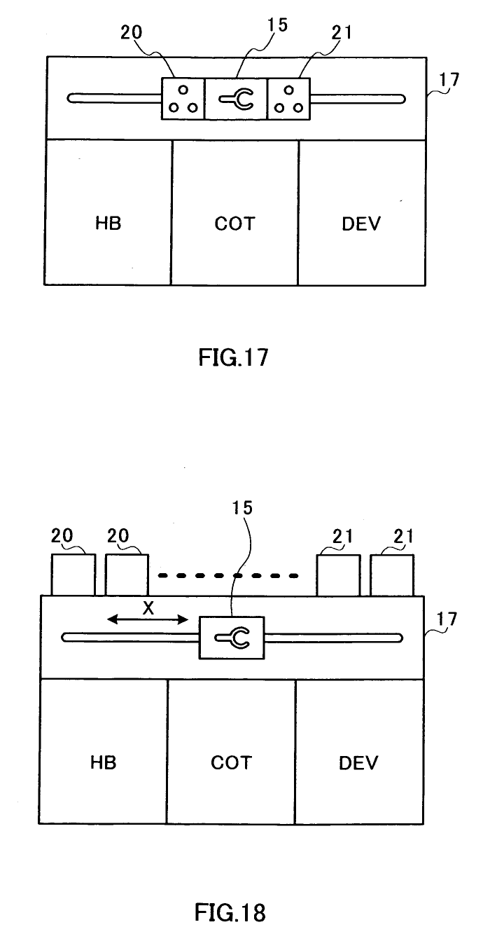

In a block having the antireflective film forming apparatus HB, coater COT and development processing apparatus DEV as the liquid processing apparatuses as described previously, the substrate delivering/receiving stations 20 and 21 are disposed on the side opposite to the antireflective film forming apparatus HB, coater COT and development processing apparatus DEV on the base 17 of the substrate carrying mechanism 15. In contrast thereto, as shown in FIG. 17, the substrate delivering/receiving stations 20 and 21 are disposed on opposite ends in the travel direction (the longitudinal direction of the base 17) of the substrate carrying mechanism 15, and configured to be movable together with the substrate carrying mechanism 15. Since the stations 20 and 21 are thus arranged, it is possible to make the time constant the substrate carrying mechanism 15 delivers the semiconductor wafer W to the substrate delivering/receiving stations 20 and 21. Further, it is made possible to move carrying positions of the substrate delivering/receiving stations 20 and 21 and the substrate carrying mechanism 10. Therefore, the substrate delivering/receiving stations 20 and 21 are moved to a minimum distance for the substrate carrying mechanism 10 to travel concurrently with a period during which the substrate carrying mechanism 10 travels, and it is thereby possible to improve throughput in deliver and receipt between the substrate delivering/receiving stations 20 and 21 and the substrate carrying mechanism 10, and the like. After the substrate carrying mechanism 15 carries the semiconductor wafer W from the antireflective film forming apparatus HB, coater COT and/or development processing apparatus DEV, the semiconductor wafer W is set at a predetermined temperature in the substrate delivering/receiving stations 20 and 21. Further, when the substrate carrying mechanism 15 carries the semiconductor wafer W to the antireflective film forming apparatus HB, coater COT and/or development processing apparatus DEV, the temperature of the semiconductor wafer W can be controlled in the substrate delivering/receiving stations 20 and 21 immediately before the wafer W is carried in, and it is thus possible to reduce fluctuations in the processing of the semiconductor wafer W.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

In a block having the antireflective film forming apparatus HB, coater COT and development processing apparatus DEV as the liquid processing apparatuses, as shown in FIG. 18, the substrate delivering/receiving stations 20 and 21 connected to the base 17 of the substrate carrying mechanism 15 of each block of the antireflective film forming apparatus HB, coater COT and development processing apparatus DEV are disposed in different positions in the X direction (the longitudinal direction of the base 17). By thus arranging, for example, the substrate carrying mechanism 10 is capable of carrying the semiconductor wafer W efficiently to a target block only by moving downward vertically, without coming into contact with the substrate delivering/receiving stations 20 and 21 of another block, and it is thus possible to improve throughput according to carriage and the like.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

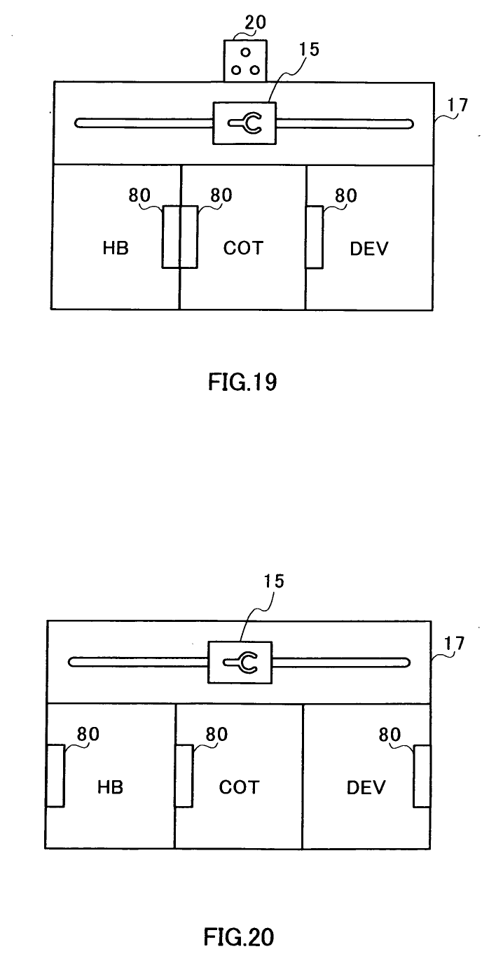

In a block having the antireflective film forming apparatus HB, coater COT and development processing apparatus DEV as the liquid processing apparatuses as described previously, a plurality of substrate delivering/receiving stations 20 and 21 is disposed on the side opposite to the antireflective film forming apparatus HB, coater COT and development processing apparatus DEV on the base 17 of the substrate carrying mechanism 15. In contrast thereto, as shown in FIG. 19, a single substrate delivering/receiving station 20 is disposed on the side (in a substantially center portion in the longitudinal direction of the base with the shortest distance from the substrate carrying mechanism 10) opposite to the antireflective film forming apparatus HB, coater COT and development processing apparatus DEV on the base 17 of the substrate carrying mechanism 15. Thus, when there is an allowance for the carrying time of the semiconductor wafer W, a plurality of substrate delivering/receiving stations is not necessary always. The region for preventing the down-flow inside the process unit section PU is thereby reduced, and the effect arises of efficiently eliminating the mist and the like inside the process unit section PU from under the apparatus. It is thereby possible to suppress adhesion of the mist and the like to the semiconductor wafer W and to enhance the yield.

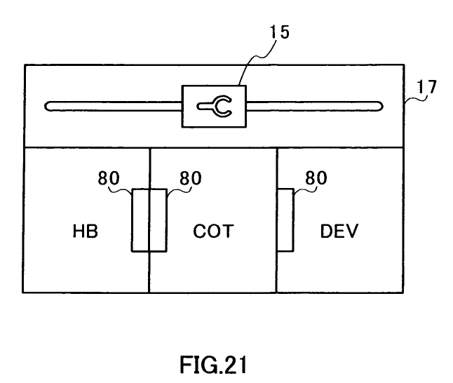

For each exhaust line of the antireflective film forming apparatus HB, coater COT and development processing apparatus DEV, the exhaust line is provided on the cassette unit section CU side together with each liquid processing apparatus in the foregoing, but naturally allowed to be disposed on the interface unit section IFU side together with each liquid processing apparatus. In this embodiment, as shown in FIG. 19, respective exhaust lines of the antireflective film forming apparatus HB and coater COT are provided close (opposite) to each other. Further, the exhaust line of the development processing apparatus DEV is provided on the cassette unit section CU side, or as shown in FIG. 21, provided on the interface unit section IFU side. Thus, the exhaust lines of the antireflective film forming apparatus HB and coater COT are provided opposite to each other, and therefore, can be integrated. In other words, the exhaust lines of the antireflective film forming apparatus HB and coater COT do not need to be different lines, and may be the same exhaust line. This is because similar liquids are collected as processing liquids in antireflective film forming apparatus HB and coater COT when the apparatuses both use the resist solution, and the collection efficiency is thus improved. It is also possible to reduce the maintenance time according to the exhaust line.

Further, for each exhaust line of the antireflective film forming apparatus HB, coater COT and development processing apparatus DEV, the exhaust line is provided on the cassette unit section CU side together with each liquid processing apparatus in the foregoing. In this embodiment, as shown in FIG. 20, respective exhaust lines of the antireflective film forming apparatus HB and coater COT are provided on the cassette unit section CU side, while the exhaust line of the development processing apparatus DEV is provided on the interface unit section IFU side. Further, as another embodiment, it is considered that respective exhaust lines of the antireflective film forming apparatus HB and coater COT are provided on the interface unit section IFU side, while the exhaust line of the development processing apparatus DEV is provided on the cassette unit section CU side. Such an arrangement is selected and set in consideration of the relationship with the storage space of the processing liquid storage container of each liquid processing section disposed in the position lower than the apparatus. In other words, for example, when a larger amount of the developing solution is consumed than the resist solution, required is the storage space of the storage container of the developing solution. Accordingly, it is preferable that the arrangement of exhaust lines is set in consideration of the storage space of each storage container of the processing liquid disposed downward.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

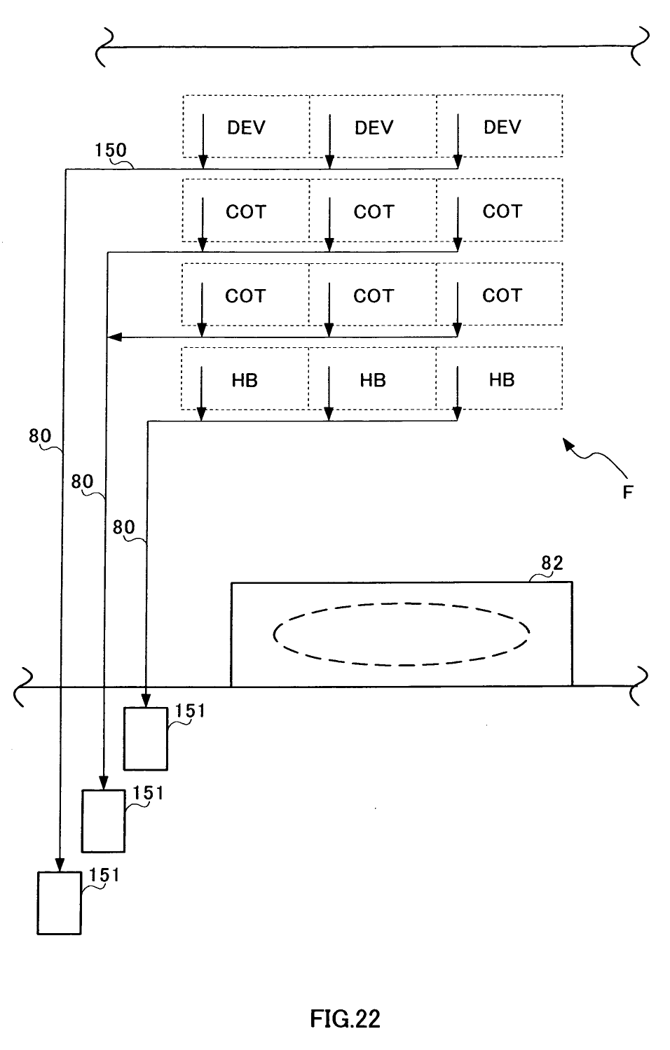

In the foregoing, a horizontal block is comprised of the antireflective film forming apparatus HB, coater COT and development processing apparatus DEV as the liquid processing apparatuses. In contrast thereto, as shown in FIGS. 22 and 23, a horizontal block is comprised of one type of liquid processing apparatuses among the antireflective film forming apparatus HB, coater COT and development processing apparatus DEV. For example, a plurality of, for example, three only development processing apparatuses DEV are provided in the horizontal direction, while forming at least one development processing apparatus DEV block, a plurality of, for example, three only coaters COT are provided in the horizontal direction under the development processing apparatus DEV block, while forming at least one, for example, a plurality of, for example, two coater COT blocks, and a plurality of, for example, three only antireflective film forming apparatuses HB are provided in the horizontal direction under the coater COT block, while forming at least one antireflective film forming apparatus HB block. In addition, the vertical positional relationship between the development processing apparatus DEV block, the antireflective film forming apparatus HB block and coater COT block may be set as appropriate based on the processing efficiency, and the number of blocks may also be set as appropriate based on the processing efficiency.

Further, the horizontal block of each liquid processing apparatus is provided with the substrate carrying mechanism 15 as described previously, but the substrate delivering/receiving stations 20 and 21 are not disposed for each horizontal block. The substrate delivering/receiving stations 20 and 21 are configured to be movable up and down for each horizontal block by the moving up/down mechanism not shown, for example, an elevator mechanism. In FIG. 23, for convenience, the stations are described as the substrate delivering/receiving station 20, and naturally, as in the substrate delivering/receiving station 20, the substrate delivering/receiving station 21 is also configured to be movable up and down for each horizontal block by the moving up/down mechanism not shown, for example, an elevator mechanism. In addition, when only the substrate delivering/receiving station 20 is capable of coping with the processing, a single station is enough to exist, instead of providing a plurality of substrate delivering/receiving stations. Further, as an arrangement position of the substrate delivering/receiving station 20, the station 20 may be disposed in any position on the side opposite to the substrate carrying mechanism 15 of the liquid processing apparatuses in the horizontal block, or may be disposed at least one end side in the longitudinal direction of the base 17 of the substrate carrying mechanism 15.

Further, as shown in FIG. 22, respective exhaust lines 80 of horizontal blocks of the liquid processing apparatuses are configured that the gas in each liquid processing apparatus in one horizontal block is exhausted downward for each liquid processing apparatus, further exhausted (in the arrangement direction of the liquid processing apparatuses of the horizontal block i.e. to one side of the cassette unit section CU side and the interface unit section IFT side) by a horizontal exhaust line 150 disposed horizontally for each horizontal block, and then, collectively exhausted vertically downward with the exhaust line 80 by each exhaust mechanism 151. In addition, each horizontal block has vertical exhaust line 80, but, for example, each horizontal block may have exhaust line 80 (first integrated exhaust line) while vertical exhaust lines 80 (second integrated exhaust lines) may be integrated into one exhaust line 80 for exhaustion. In addition, in a plurality of horizontal blocks, when a plurality of horizontal blocks exists that are comprised of the same types of liquid processing apparatuses, in FIG. 23, since two horizontal blocks of the coaters COT exist, the exhaust lines are configured to be able to collectively exhaust at some midpoint of the lines.

Thus, since the same types of liquid processing apparatuses constitute a horizontal block, the need is eliminated of consideration on each liquid processing section of the arm 22 of the substrate carrying mechanism 15 corresponding to the horizontal block as described previously, and it is thereby possible to resolve problems of cross contamination and the like, and to improve the yield of semiconductor wafers W. Further, since horizontal blocks are capable of sharing the substrate delivering/receiving stations 20 and 21, it is possible to decrease the size of the apparatus system and reduce the cost of the apparatus. In addition, the exhaust line 80 is preferably disposed between stacked horizontal blocks for each horizontal block. For this arrangement, the exhaust line 80 may be provided in the base 17.

Described next is another embodiment in an arrangement of the heater section HPB1 and heater section HPB2 of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

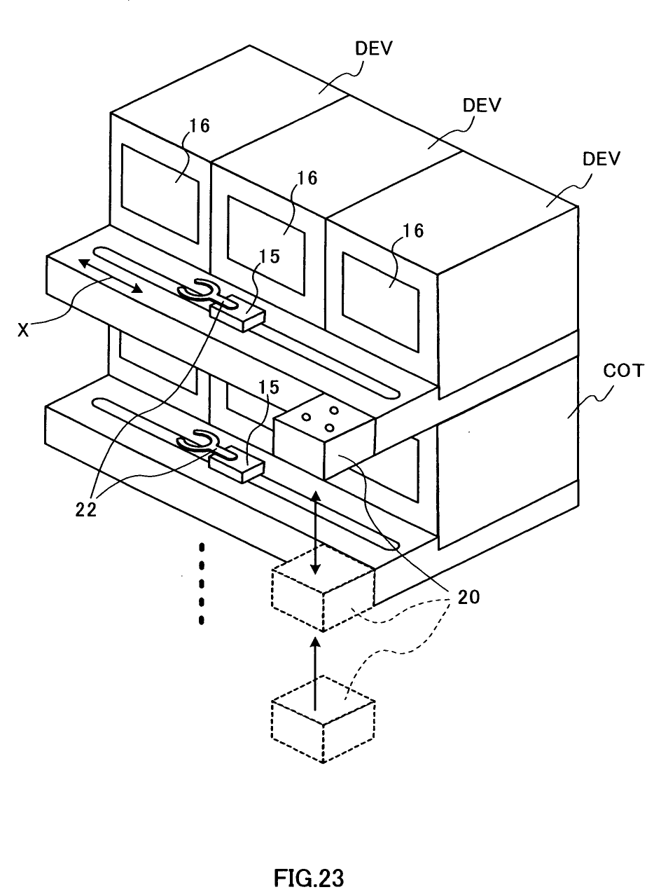

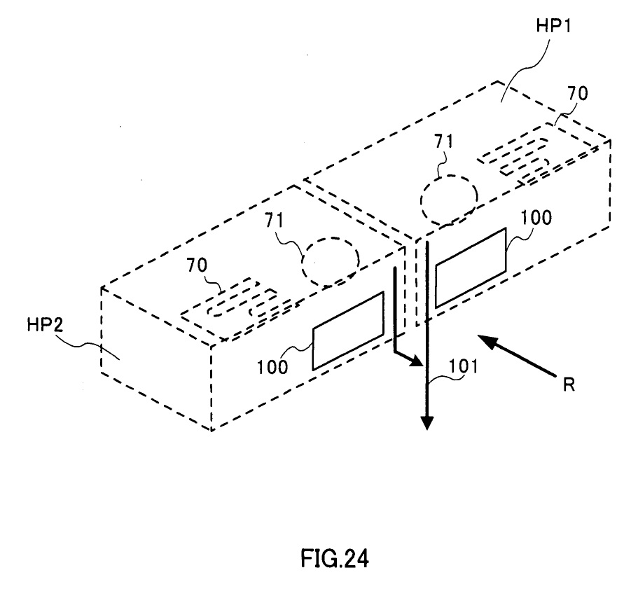

In the foregoing, the heaters HP1 and HP2 respectively of the heater sections HPB1 and HPB2 are configured so that respective temperature adjustment mechanisms 70 are provided adjacent to each other. In contrast thereto, as shown in FIG. 24, the heaters HP1 and HP2 are configured so that respective heating mechanisms 71 are provided adjacent to each other. In such a configuration, since respective exhaust lines 101 of the heaters HP1 and HP2 are disposed adjacent to each other, it is made easy to connect and integrate the exhaust lines into a single line, heat diffusion to the wall of the apparatus is suppressed as compared with the case of a plurality of exhaust lines 101, and it is possible to make the atmosphere circulation system efficient according to the atmosphere of the down-flow inside the process unit section PU and the like. Further, since heat diffusion to the wall of the apparatus is suppressed, it is possible to inhibit heat transfer to another section. Furthermore, since the doors 100 for maintenance come close to each other, the worker is capable of accessing promptly, thereby improving the operation efficiency.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

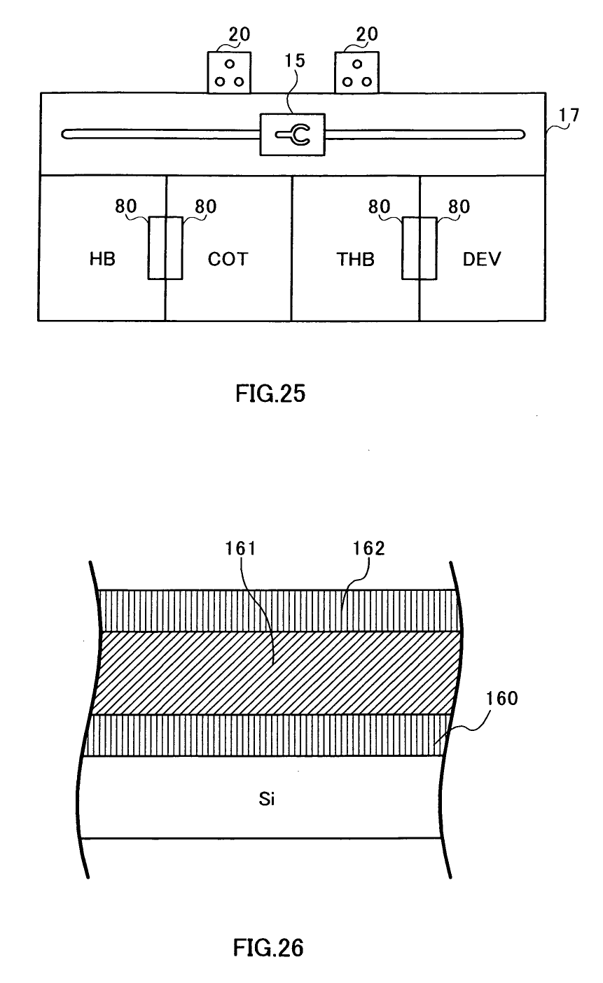

A horizontal block has the antireflective film forming apparatus HB, coater COT and development processing apparatus DEV as the liquid processing apparatuses as described previously, but as shown in FIG. 25, a fourth liquid processing apparatus is disposed together between the coater COT and development processing apparatus DEV. For example, the fourth liquid processing apparatus is a second antireflective film forming apparatus THB to form a coating, for example, a coating antireflective film, on the processing surface of the semiconductor wafer W subjected to the development processing in the development processing apparatus DEV. For the film by the antireflective film forming apparatus THB, as shown in FIG. 26, first, an antireflective film 160 is formed on the processing surface of the semiconductor wafer W as a primary coating by the antireflective film forming apparatus HB that is the first antireflective film forming apparatus. Then, a resist film 161 is formed by the coater COT, subjected to the exposure processing in the exposure apparatus 3, and further subjected to the development processing in the development processing apparatus DEV. Subsequently, an antireflective film 162 is formed on the surface of the resist film 161 on the processing surface of the semiconductor wafer W as a coating film by the antireflective film forming apparatus THB that is the second antireflective film forming apparatus.

Exhaust lines of the liquid processing apparatuses are provided on the side in contact respectively with the liquid processing apparatuses. Thus, when another liquid processing apparatus is installed, only by extending the travel distance of the substrate carrying mechanism 15, it is possible to cope with each liquid processing apparatus with ease. In addition, even when the travel distance of the substrate carrying mechanism 15 is extended, the substrate delivering/receiving stations 20 and 21 can be disposed in positions enabling access of the arm 11 of the substrate carrying mechanism 10. Further, in this embodiment, one horizontal block is comprised of the antireflective film forming apparatus HB, coater COT, development processing apparatus DEV and antireflective film forming apparatus THB. However, as shown in FIG. 22 described previously, horizontal blocks may be stacked and disposed which include, from down to up, a horizontal block comprised of a plurality of only antireflective film forming apparatuses HB, a horizontal block comprised of a plurality of only coaters COT, a horizontal block comprised of a plurality of only development processing apparatuses DEV, and a horizontal block comprised of a plurality of only antireflective film forming apparatuses THB. Naturally, the substrate delivering/receiving stations 20 and 21 are configured to be movable up and down by the moving up/down mechanism not shown, and may be shared in each horizontal block. The same effect as in the forgoing is obtained.

Described next is another embodiment in a block of the antireflective film forming apparatus HB, coater COT, antireflective film forming apparatus THB and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

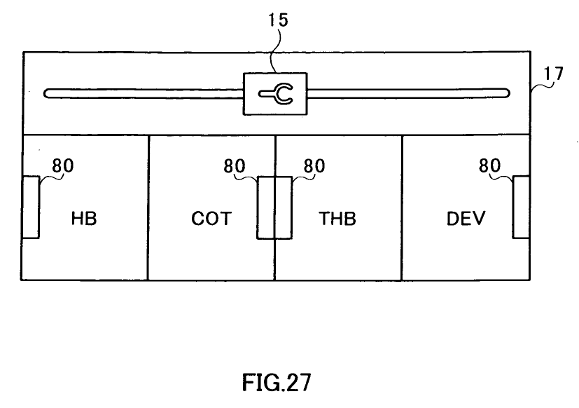

In the foregoing, the exhaust lines of the antireflective film forming apparatus HB, coater COT, antireflective film forming apparatus THB and development processing apparatus DEV as the liquid processing apparatuses are disposed on the respective adjacent liquid processing apparatus side. In contrast thereto, as shown in FIG. 27, the exhaust lines of adjacent liquid processing apparatuses in the center, for example, of the coater COT and antireflective film forming apparatus THB are disposed on the side of liquid processing apparatuses adjacent to each other, while outer liquid processing apparatuses, for example, the antireflective film forming apparatus HB and development processing apparatus DEV have respective exhaust lines 80 on the outer side. Since the exhaust lines are thus disposed and configured, it is possible to concentrate arrangement regions of processing liquid storage containers disposed in the lower position on the center to secure.

Described next is another embodiment in a block of the antireflective film forming apparatus HB, coater COT, antireflective film forming apparatus THB and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

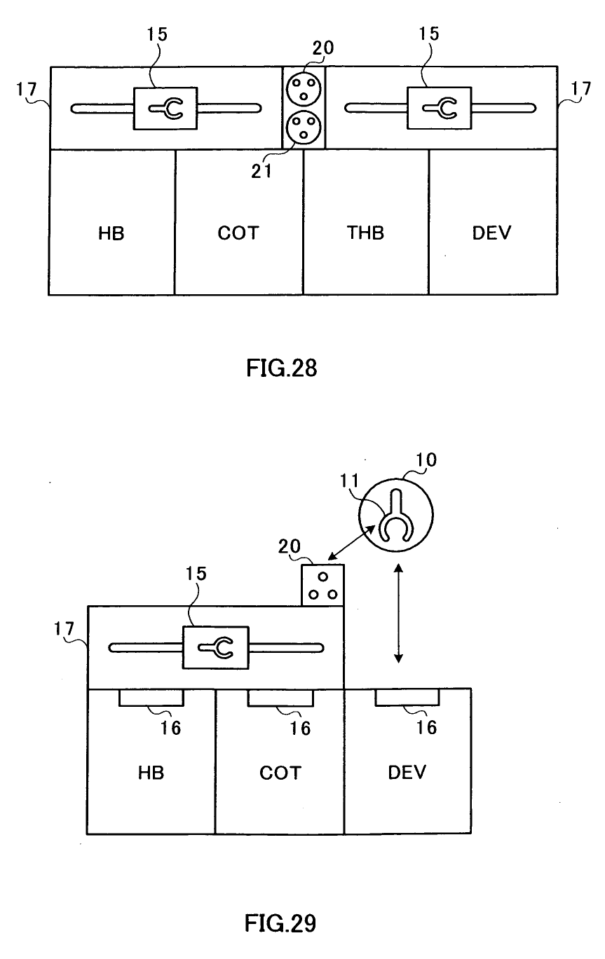

In the foregoing, a plurality of liquid processing apparatuses is formed as a horizontal block, and a single substrate carrying mechanism 15 is provided for each horizontal block. In contrast thereto, as shown in FIG. 28, a plurality of, for example, two substrate carrying mechanisms 15 are disposed for one horizontal block in parallel with each other along the linear arrangement direction of the plurality of liquid processing apparatuses. Further, the substrate delivering/receiving stations 20 and 21 are disposed between the substrate carrying mechanisms 15. In addition, the substrate delivering/receiving stations 20 and 21 are disposed in the lengthwise direction, but may be disposed in a line in the linear arrangement direction of a plurality of liquid processing apparatuses. Further, a plurality of, for example, two substrate delivering/receiving stations 20 and 21 are provided, but four substrate delivering/receiving stations 20 and 21 may be disposed in order for two substrate carrying mechanisms 15 to separately use. Furthermore, when only one substrate delivering/receiving station is enough, a single station may be provided. Still furthermore, substrate delivering/receiving stations 20 and 21 may be configured to be moved up and down by the moving up/down mechanism not shown to enable its sharing with the substrate carrying mechanism 15 of another lower or upper horizontal block. Thus, when the number of liquid processing apparatuses increases in one horizontal block, since a plurality of substrate carrying mechanisms is provided and substrate delivering/receiving stations 20 and 21 are disposed between the substrate carrying mechanisms, it is possible to provide a system capable of flexibly coping with the arrangement of apparatuses even when the number of liquid processing apparatuses increases in one horizontal block.

Described next is another embodiment in a block of the antireflective film forming apparatus HB, coater COT and development processing apparatus DEV as liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

In the foregoing, the antireflective film forming apparatus HB, coater COT and development processing apparatus DEV as liquid processing apparatuses are formed in a horizontal block. In contrast thereto, as shown in FIG. 29, the horizontal block is comprised of a plurality of liquid processing apparatuses, for example, the antireflective film forming apparatus HB and coater COT, and the substrate carrying mechanism 15 is capable of accessing the antireflective film forming apparatus HB and coater COT to carry the semiconductor wafer W. The development processing apparatus DEV is provided together with the antireflective film forming apparatus HB and coater COT, and substantially constitutes part of the horizontal block, but for carrying the semiconductor wafer W to the development processing apparatus DEV, the arm 11 of the substrate carrying mechanism 10 is configured to directly carry the semiconductor wafer W. Thus, for example, when a liquid processing apparatus having no need of disposing a plurality of such apparatuses exists, or the number of liquid processing apparatuses is smaller than numbers of other liquid processing apparatuses, by directly carrying the wafer W by the arm 11 of substrate carrying mechanism 10, it is possible to improve throughput according to the carrying.

Described next is another embodiment in a horizontal block in the liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

FIG. 30 shows a configuration where, for example, a plurality of development processing apparatuses DEV constitutes one horizontal block, and under the block, as another block, a plurality of liquid processing apparatuses, for example, a plurality of coaters COT constitutes one horizontal block. In this configuration, the base 17 of the substrate carrying mechanism 15 is not disposed for each block. The base 17 of the substrate carrying mechanism 15 is configured to be movable up and down for each horizontal block by the moving up/down mechanism not shown, for example, an elevator mechanism. Further, the substrate delivering/receiving stations 20 and 21 are not provided for each horizontal block. The substrate delivering/receiving stations 20 and 21 are configured to be movable up and down for each horizontal block by the moving up/down mechanism not shown, for example, an elevator mechanism. In FIG. 30, for convenience, the station is described as the substrate delivering/receiving station 20, and naturally, as in the substrate delivering/receiving station 20, the substrate delivering/receiving station 21 is also configured to be movable up and down for each horizontal block by the moving up/down mechanism not shown, for example, an elevator mechanism. In addition, when only the substrate delivering/receiving station 20 is capable of coping with the processing, a single station is enough to exist, instead of providing a plurality of substrate delivering/receiving stations. Further, as an arrangement position of the substrate delivering/receiving station 20, the station 20 may be disposed in any position on the side opposite to the substrate carrying mechanism 15 of the liquid processing apparatuses in the horizontal block, or may be disposed at least one end side in the longitudinal direction of the base 17 of the substrate carrying mechanism 15.

Thus, the base 17 of the substrate carrying mechanism 15 and substrate delivering/receiving stations are configured to be movable up and down independently of each other, and it is possible to implement carrying of the semiconductor wafer W to each horizontal block, resulting in merits of reducing the size of the system and further reducing the cost of the apparatus. Furthermore, when the substrate delivering/receiving stations 20 and 21 are fixed to the base 17 of the substrate carrying mechanism 15 configured to be movable up and down, since the need is eliminated of the moving up/down mechanism on the substrate delivering/receiving stations 20, 21 sides, it is possible to improve the supportability of the system to installation of more liquid processing apparatuses, and to reduce the size of the system and the cost of the apparatus. In addition, when the base 17 of the substrate carrying mechanism 15 is moved and traveled, it is not necessary that the base 17 of the substrate carrying mechanism 15 is provided between horizontal blocks. Such provision is required for the reason of fixing the base 17 of the substrate carrying mechanism 15 and the horizontal unit. Another reason is production efficiency such that the horizontal block and base 17 of the substrate carrying mechanism 15 are assembled alternately in manufacturing. Accordingly, as shown in FIG. 30, in this embodiment, the horizontal unit is separated from the base 17 of the substrate carrying mechanism 15.

Described next is another embodiment using the substrate carrying mechanism 15 and substrate delivering/receiving stations 20 and 21 of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

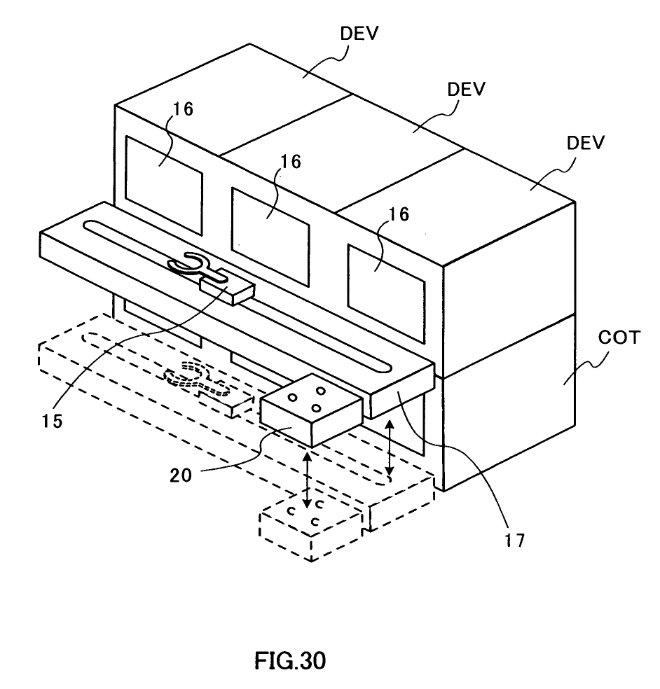

In the foregoing, a plurality of liquid processing apparatuses is formed in a horizontal block, however, as shown in FIG. 31, a plurality of heaters constitutes a horizontal block. In this configuration, the base 17 of the substrate carrying mechanism 15 is not disposed for each block. The base 17 of the substrate carrying mechanism 15 is configured to be movable up and down for each horizontal block by the moving up/down mechanism not shown, for example, an elevator mechanism. Further, the substrate delivering/receiving stations 20 and 21 are not provided for each horizontal block. The substrate delivering/receiving stations 20 and 21 are configured to be movable up and down for each horizontal block by the moving up/down mechanism not shown, for example, an elevator mechanism. In FIG. 31, for convenience, the station is described as the substrate delivering/receiving station 20, and naturally, as in the substrate delivering/receiving station 20, the substrate delivering/receiving station 21 is also configured to be movable up and down for each horizontal block by the moving up/down mechanism not shown, for example, an elevator mechanism. In addition, when only the substrate delivering/receiving station 20 is capable of coping with the processing, a single station is enough to exist, instead of providing a plurality of substrate delivering/receiving stations. Further, as an arrangement position of the substrate delivering/receiving station 20, the station 20 may be disposed in any position on the side opposite to the substrate carrying mechanism 15 of the heaters in the horizontal block, or may be disposed at least one end side in the longitudinal direction of the base 17 of the substrate carrying mechanism 15. Further, without using the substrate carrying mechanism 10, the substrate carrying mechanism 15 may be configured to carry the semiconductor wafer W to/from the heaters.

Thus, the base 17 of the substrate carrying mechanism 15 and substrate delivering/receiving stations are configured to be movable up and down independently of each other, and it is possible to implement carrying of the semiconductor wafer W to each horizontal block. Therefore, it is possible to improve the supportability of the system to installation of more heaters, resulting in merits of reducing the size of the system and the cost of the apparatus. Further, when the substrate delivering/receiving stations 20 are fixed to the base of the substrate carrying mechanism 15 configured to be movable up and down, since the need is eliminated of the moving up/down mechanism on the substrate delivering/receiving stations 20, 21 sides, it is possible to further reduce the size of the system and the cost of the apparatus.

Described next is another embodiment in a horizontal block in the liquid processing apparatuses of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

In the foregoing, a horizontal block is comprised of the antireflective film forming apparatus HB, coater COT and development processing apparatus DEV as the liquid processing apparatuses. In contrast thereto, as shown in FIG. 32, a horizontal block is comprised of one type of liquid processing apparatuses among the antireflective film forming apparatus HB, coater COT and development processing apparatus DEV. For example, a plurality of, for example, three only coaters COT are provided in the horizontal direction, while forming at least one coater COT block, and under the coaters COT, a plurality of, for example, three only development processing apparatuses DEV are provided in the horizontal direction, while forming a development processing apparatus DEV block. Further, each horizontal block is provided with the base of the substrate carrying mechanism 15. On each base 17 of the substrate carrying mechanism 17 is provided a processing liquid supply moving mechanism 161 which is configured to be able to travel in the X direction on a travel path 160 in parallel with and between the substrate carrying mechanism 15 and the liquid processing apparatuses, and to supply a predetermined processing liquid to each of the liquid processing apparatuses within the horizontal block. In other words, a plurality of liquid processing apparatuses in a horizontal block uses the same processing liquid, and when each of the liquid processing apparatuses is provided with a liquid supply mechanism, for example, a processing liquid nozzle, the apparatus becomes large in size and complicated in mechanism. Accordingly, when the same type of liquid processing apparatuses exist in a block, by sharing the liquid supply mechanism, it is possible to reduce the size and cost of the system.

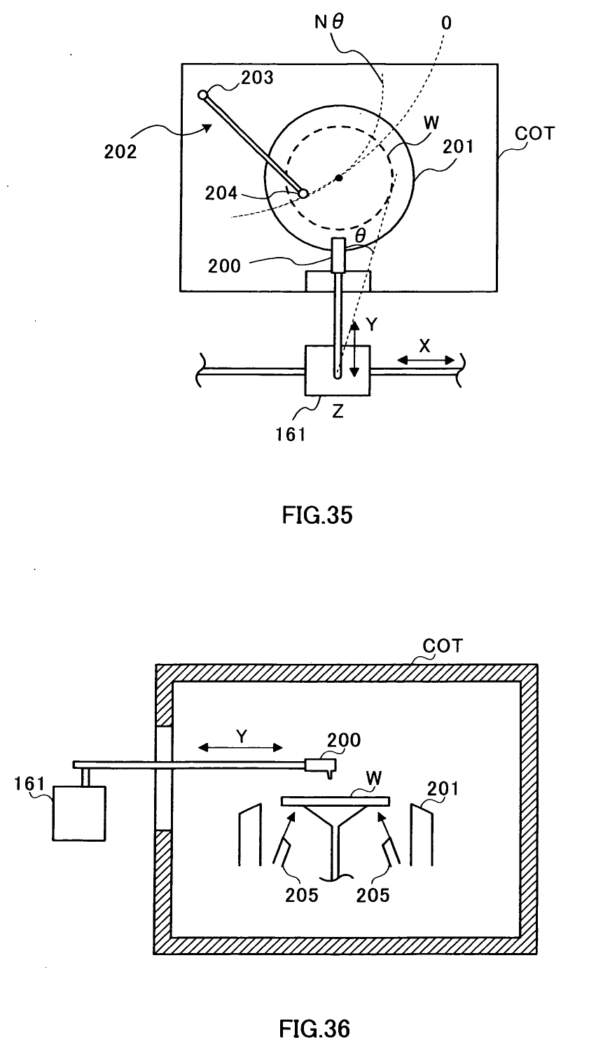

As shown in FIG. 35, a processing liquid nozzle 200 of the processing liquid supply moving mechanism 161 is configured to be able to travel in the direction to expand the liquid processing nozzle 200 perpendicular to X in which the base 17 travels to supply the processing liquid to at least center portion of the semiconductor wafer W disposed in a cup 201 that is provided inside a liquid processing apparatus, for example, the resist coater COT to process a processing target substrate inside the apparatus, in the vertical direction (Z direction) for the processing liquid nozzle 200 to supply the processing liquid from a predetermined height position and the like, and in the rotation direction (θ direction) of the processing liquid nozzle 200. It is possible to supply a processing liquid, for example, a rinse solution while moving the processing liquid nozzle 200 in this rotation direction, or when the liquid processing apparatus is the development processing apparatus, it is possible to supply a processing liquid, for example, the developing solution from the processing liquid nozzle 200 to the cup 201 and semiconductor wafer W while moving the solution in the X direction to perform the processing. In addition, when the liquid processing apparatus is the development processing apparatus and supplies the processing liquid, for example, a rinse solution, the processing liquid nozzle 200 may be moved in the rotation direction (θ direction) to supply the liquid, or may be moved in the X direction, for example, reciprocate to perform the processing.

Further, inside each liquid processing apparatus, for example, each resist coater COT (development processing chamber and/or antireflective film forming chamber) is provided a processing liquid supply mechanism 202 inside the liquid processing apparatus to supply a processing liquid, for example, a rinse solution to the semiconductor wafer W. The processing liquid supply mechanism 202 inside the liquid processing apparatus is fixed in its axis 203 and configured to be able to supply a processing liquid onto the semiconductor wafer W while rotating a processing liquid nozzle 204 in the Nθ direction. Furthermore, not shown in the figure, inside each liquid processing apparatus, for example, each resist coater COT (development processing chamber or the like) is disposed a processing liquid nozzle 205 that is a second processing liquid supply mechanism inside the liquid processing apparatus to supply a processing liquid, for example, a rinse solution to the backside of the semiconductor wafer W inside the cup 201. In addition, in this embodiment, the first processing liquid supply mechanism 202 inside the liquid processing apparatus is configured to rotate, but may be configured to be movable in the same direction (i.e. parallel traveling) with X traveling of the processing liquid supply moving mechanism 161 with the cup 201 between the mechanisms 202 and 161, or may be disposed on the horizontal block arrangement direction side while being configured to be movable in the direction (i.e. Y direction) perpendicular to X traveling of the processing liquid supply moving mechanism 161. In addition, when the processing liquid supplied from the processing liquid supply mechanism 202 inside the liquid processing apparatus is, for example, the resist solution in the case of the resist coater COT, while being, for example, the developing solution in the case of the development processing apparatus DEV, it is also preferable that the processing liquid supplied from the processing liquid nozzle 200 of the processing liquid supply moving mechanism 161 is a rinse solution. Further, also when the processing liquid nozzle 200 of the processing liquid supply moving mechanism 161 serves the function of the first processing liquid supply mechanism 202 inside the liquid processing apparatus to construct a system with the processing liquid supply mechanism 202 eliminated, it is preferable that a processing liquid nozzle 205 is provided to supply a processing liquid, for example, a rinse solution to the backside of the semiconductor wafer W from the backside of the semiconductor wafer W.

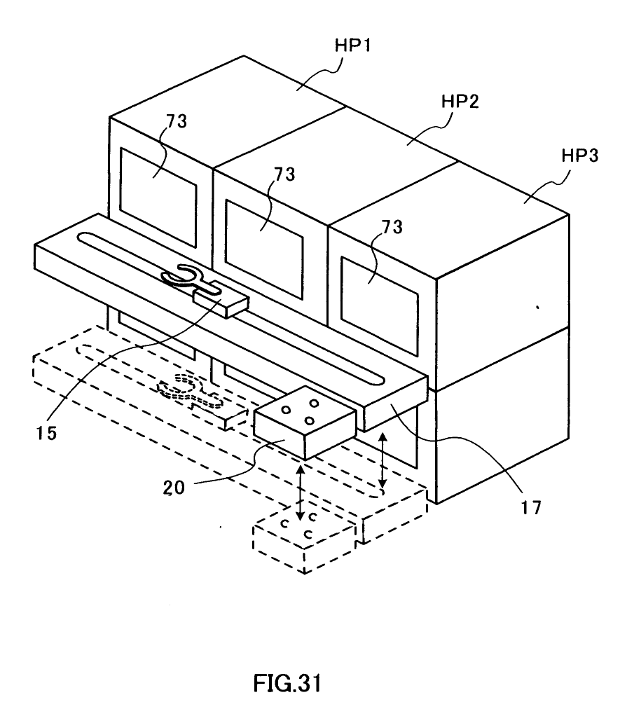

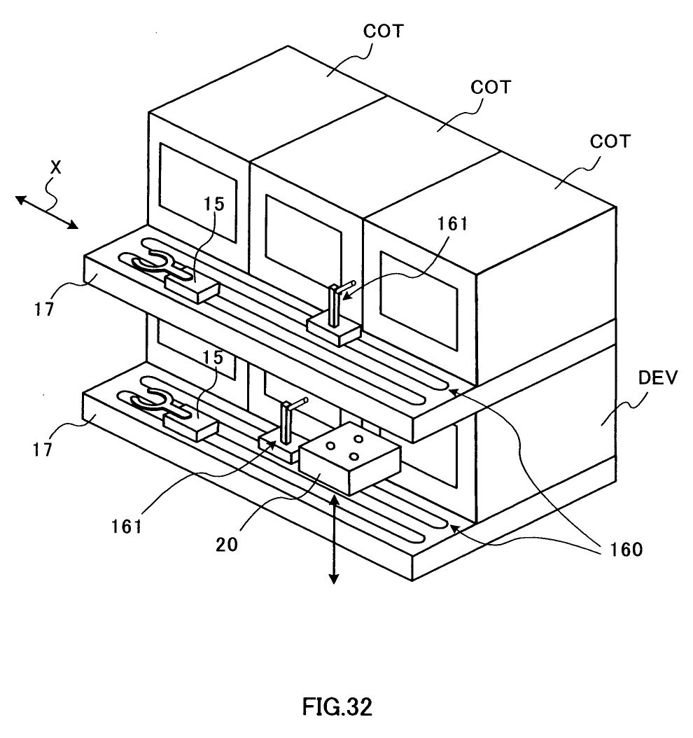

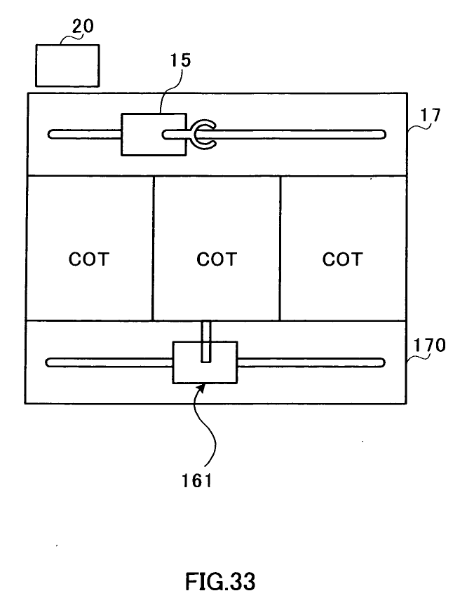

In addition, the substrate carrying mechanism 15 and processing liquid supply moving mechanism 161 are configured to be movable independently of each other, and are controlled to interfere with each other. Further, the processing liquid supply moving mechanism 161 may be disposed in another place, for example, on the side opposite to the substrate carrying mechanism with the liquid processing apparatus group between the mechanisms 15 and 161 as shown in FIG. 33. The processing liquid supply moving mechanism 161 supplies the resist solution in the coater COT block, while supplying the developing solution in the development processing apparatus DEV block, and further, may be configured to have a plurality of processing liquid nozzles, instead of one liquid supply mechanism, for example, one liquid supply nozzle, and select the nozzle to supply the processing liquid. For example, the processing liquid supply moving mechanism 161 in the development processing apparatus DEV block may be configured to have a developing solution nozzle and rinse solution nozzle to select as appropriate, and to be able to supply the solution to each liquid processing apparatus.

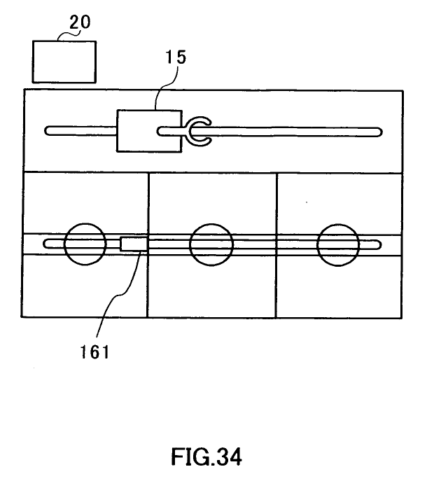

Further, when a horizontal block has different types of liquid processing apparatuses, for example, the coater COT and development processing apparatus DEV, the processing liquid supply moving mechanism 161 of the horizontal block may be configured to have a plurality of types of processing nozzles, for example, a developing solution nozzle and rinse solution nozzle to select as appropriate to supply. It is thereby possible to efficiently improve maintenance time and the like according to the processing liquid supply line. Furthermore, as shown in FIG. 34, when the processing liquid supply moving mechanism 161 is provided above the liquid processing apparatus block, for example, the coater COT, and configured to travel along the center positions of the cups inside the liquid processing apparatuses, i.e. the positions to supply the processing liquid to the semiconductor wafer W in the cup, the processing liquid supply moving mechanism 161 eliminates the need of the mechanism for expanding the liquid supply nozzle (in the Y direction), or enables the expandable distance to be shortened, and it is thereby possible to reduce the size of the moving mechanism.

Described next is another embodiment in the processing liquid supply moving mechanism 161 of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

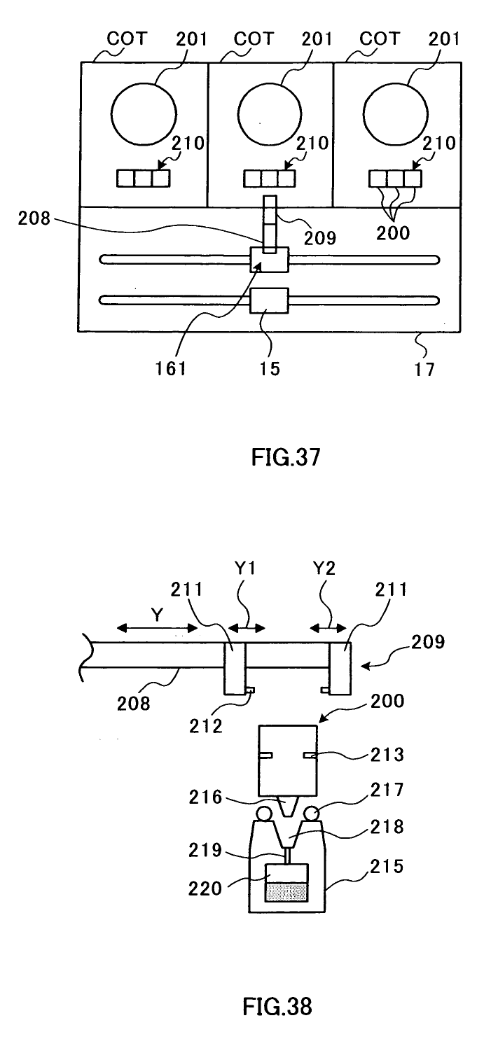

In the foregoing, the case is described that the processing liquid supply moving mechanism 161 is provided with the processing liquid nozzle 200. For the selection and arrangement of processing liquid nozzles 200, as shown in FIG. 37, the processing liquid supply moving mechanism 161 is provided with an arm 208, and further, at the front end portion of the arm 208, with a holding mechanism 209 that holds the processing liquid nozzle 200 as a processing liquid supply mechanism. In the holding mechanism 209, for example, as shown in FIG. 38, two bearing members 211 are configured to be able to come close and apart to/from each other in the Y direction (Y1 and Y2 directions in the figure), and each mechanism 209 is configured to be able to be held by engaging by a coupling mechanism, for example, a convex portion 212 provided in the bearing member 211 in a coupling mechanism, for example, a concave portion 213 provided on the processing liquid nozzle 200 side. In addition, while this embodiment describes such a holding mechanism, the invention is not limited thereto, and naturally, any mechanisms that hold and move the processing liquid nozzle 200 can be used. Further, it is configured that at least one processing liquid nozzle 200 is disposed in a predetermined area 210 on the processing liquid supply moving mechanism 161 side of the cup 201 inside each liquid processing apparatus. The processing liquid nozzle(s) 200 disposed in the predetermined area 210 is provided, for each processing liquid nozzle 200, with a processing liquid nozzle arrangement mechanism 215 as a base of the processing liquid nozzle 200. The processing liquid nozzle arrangement mechanism 215 is provided with an airtight member, for example, an O-ring to make a processing liquid ejection portion 216 of the processing liquid nozzle airtight, and the processing liquid ejection portion 216 is configured to be airtight by a space portion 218.

Further, the space portion 218 of the processing liquid nozzle arrangement mechanism 215 is configured to able to supply a volatile gas from a storage portion 220 that stores a volatile dry preventive liquid (in the case of a predetermined resist solution, it is preferable using the same liquid as a solvent of the resist solution) via a communication hole 219 by the processing liquid ejection portion 216 of the liquid processing nozzle to prevent the processing liquid from deteriorating or drying. In addition, as the processing liquid nozzles 200 in the predetermined area 210, as described previously, when the liquid processing apparatus is, for example, the coater COT or THB, the nozzles 200 supply a plurality of (at least one type) liquids, resist solution and/or rinse solution. When the liquid processing apparatus is the development processing apparatus DEV, the nozzles 200 supply a plurality of (at least one type) liquids, developing solution and/or rinse solution. Thus, it is possible to supply the processing liquid to the semiconductor wafer W inside the cup 201 while selecting the processing liquid nozzle disposed in each liquid processing apparatus as appropriate by the processing liquid supply moving mechanism 161 from outside the liquid processing apparatus, each liquid processing apparatus thus eliminates the need of having a mechanism of moving the processing liquid nozzle, and it is possible to achieve reductions in size and cost of the system. In addition, a plurality of processing liquid nozzles 200 disposed in the predetermined area 210 is arranged linearly in the direction parallel with the traveling direction in which the processing liquid supply moving mechanism 161 is self-propelled to travel, but may be arranged in the shape of an arc (for example, on the same diameter) in the θ direction of the processing liquid supply moving mechanism 161. By this means, the processing liquid supply moving mechanism 161 is capable of selecting and holding the processing liquid nozzle 200 in the θ direction, extendable direction and vertical direction without traveling, and it is thus possible to suppress fluctuations in the down-flow by traveling of the processing liquid supply moving mechanism 161.

In addition, in the case of such a configuration, when the liquid processing apparatus is the resist coater COT and/or antireflective film forming apparatus HB and the processing liquid nozzle 200 is a supply nozzle of the resist solution, the processing liquid supply moving mechanism 161 first travels to near a carrying inlet of the selected predetermined resist coater COT, extends the arm 208 from outside the liquid processing apparatus to inside the liquid processing apparatus, and selects a predetermined processing liquid nozzle 200 in the predetermined area 210 inside the liquid processing apparatus to hold by the holding mechanism 209. Subsequently, the processing liquid nozzle 200 is positioned above the center portion of the semiconductor wafer W by the holding mechanism 209 traveling to be halted, and coats the resist solution on the processing surface of the rotating semiconductor wafer W to form a resist film, or supplies the resist solution to the center portion or the center portion and its vicinity on the processing surface of the halted semiconductor wafer W, and then, the semiconductor wafer W is rotated to form a resist film. Subsequently, the semiconductor wafer W is supplied with the rinse solution by the first processing liquid supply mechanism 202 inside the liquid processing apparatus and/or the processing liquid nozzle 205 that is the second processing liquid supply mechanism inside the liquid processing apparatus inside the liquid processing apparatus, and undergoes the processing.

Further, when the liquid processing apparatus is the development processing apparatus DEV and the processing liquid nozzle 200 is a supply nozzle of the developing solution, the processing liquid supply moving mechanism 161 first travels to near a carrying inlet of the selected predetermined development processing apparatus DEV, extends the arm 208 from outside the liquid processing apparatus to inside the liquid processing apparatus, and selects a predetermined processing liquid nozzle 200 in the predetermined area 210 inside the liquid processing apparatus to hold by the holding mechanism 209. Subsequently, the processing liquid nozzle 200 is positioned in a position above or side to the semiconductor wafer W by the holding mechanism 209 traveling to be halted, and supplies the developing solution on the processing surface of the halted semiconductor wafer W, or supplies the developing solution on the processing surface of the halted semiconductor wafer W and cup 201 while traveling in the X direction in the X direction. After the developing processing by the developing solution has proceeded for a predetermined time, the semiconductor wafer W is moved downward, placed on a spin chuck configured to be rotatable, and rotated to blow the developing solution. Then, the semiconductor wafer W is supplied with the rinse solution by the first processing liquid supply mechanism 202 inside the liquid processing apparatus and/or the processing liquid nozzle 205 that is the second processing liquid supply mechanism inside the liquid processing apparatus inside the liquid processing apparatus, and undergoes the processing.

Described next is another embodiment in the processing liquid supply moving mechanism 161 of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

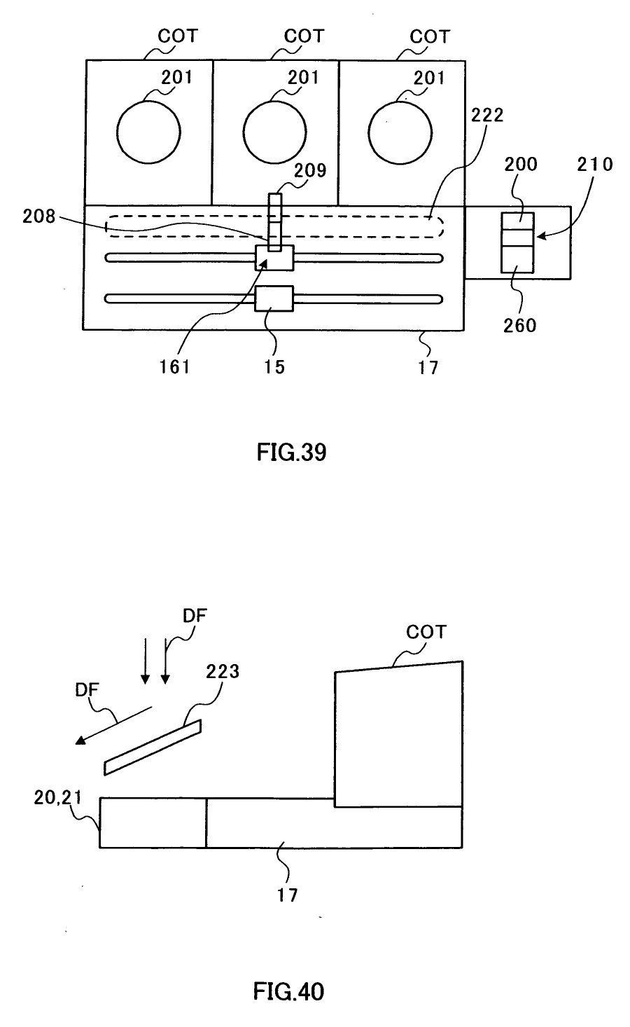

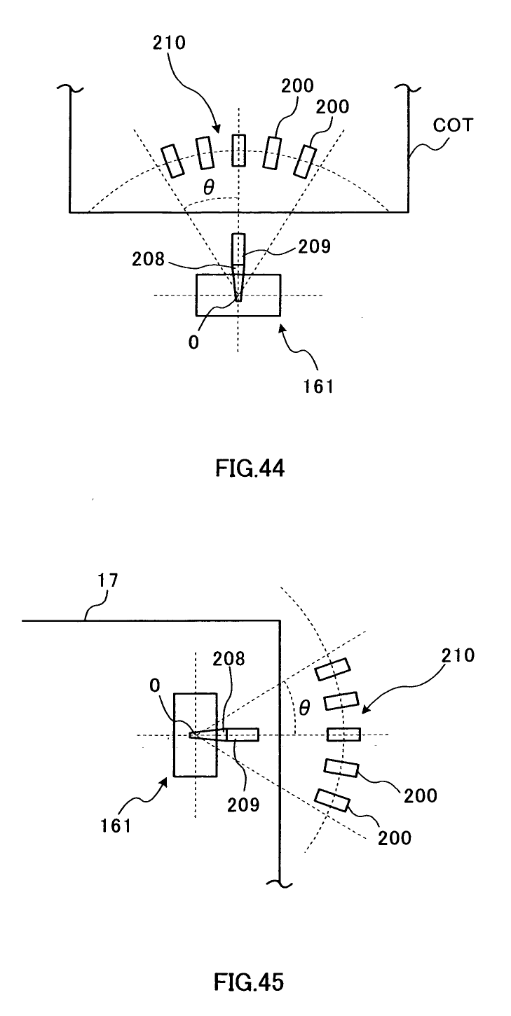

In the foregoing, the case is described that the processing liquid nozzle 200 is provided inside each liquid processing apparatus. In contrast thereto, as shown in FIG. 39, the processing liquid nozzle 200 is disposed outside the liquid processing apparatus, not inside each liquid processing apparatus, and configured so that at least one processing liquid nozzle 200 is disposed in the predetermined area 210 on at least one side in the linear X direction and in the longitudinal direction of the processing liquid supply moving mechanism 161. In such a configuration, the need is eliminated of providing the predetermined area 210 to dispose the processing liquid nozzle 200 inside each liquid processing apparatus, and the merit arises of enabling the size of each liquid processing apparatus to be decreased. Further, since each liquid processing apparatus does not need to have the processing liquid nozzle 200, it is possible to achieve reductions in size and cost of the system. Alternately, as the predetermined area 210 to dispose the processing liquid nozzle 200, it is preferable that the nozzle 200 is disposed in a region (“222” in the figure) between the liquid processing apparatus and processing liquid supply moving mechanism 161. In addition, a plurality of processing liquid nozzles 200 disposed in the predetermined area 210 is arranged linearly in the direction perpendicular to the traveling direction in which the processing liquid supply moving mechanism 161 is self-propelled to travel, and further, as shown in FIGS. 44 and 45, may be arranged in the shape of an arc or on the curve (for example, on the same diameter) in the θ direction as the rotation axis of the processing liquid supply moving mechanism 161 as an axis. The processing liquid supply moving mechanism 161 is thereby capable of selecting and holding the processing liquid nozzle 200 in the θ direction, extendable direction and vertical direction without traveling, and it is thus possible to dispose more processing liquid nozzles 200 in the predetermined area 210.

In addition, in the case of such a configuration, when the liquid processing apparatus is the resist coater COT and/or antireflective film forming apparatus HB and the processing liquid nozzle 200 is a supply nozzle of the resist solution, first, the processing liquid supply moving mechanism 161 selects a predetermined processing liquid nozzle 200 in the predetermined area 210 outside the liquid processing apparatus to hold by the holding mechanism 209. The processing liquid supply moving mechanism 161 travels to near a carrying inlet of the selected predetermined resist coater COT, extends the arm 208 from outside the liquid processing apparatus to inside the liquid processing apparatus, and positions the processing liquid nozzle 200 above the center portion of the semiconductor wafer W by moving the holding mechanism 209 to halt therein. The processing liquid nozzle 200 coats the resist solution on the processing surface of the rotating semiconductor wafer W to form a resist film, or supplies the resist solution to the center portion or the center portion and its vicinity on the processing surface of the halted semiconductor wafer W, and then, the semiconductor wafer W is rotated to form a resist film. Subsequently, the semiconductor wafer W is supplied with the rinse solution by the first processing liquid supply mechanism 202 inside the liquid processing apparatus and/or the processing liquid nozzle 205 that is the second processing liquid supply mechanism inside the liquid processing apparatus inside the liquid processing apparatus, and undergoes the processing.

Further, when the liquid processing apparatus is the development processing apparatus DEV and the processing liquid nozzle 200 is a supply nozzle of the developing solution, first, the processing liquid supply moving mechanism 161 selects a predetermined processing liquid nozzle 200 in the predetermined area 210 outside the liquid processing apparatus to hold by the holding mechanism 209. Then, the processing liquid supply moving mechanism 161 travels to near a carrying inlet of the selected predetermined development processing apparatus DEV, extends the arm 208 from outside the liquid processing apparatus to inside the liquid processing apparatus, and positions the processing liquid nozzle 200 in a position above or side to the semiconductor wafer W by moving the holding mechanism 209 to halt therein. The processing liquid nozzle 200 supplies the developing solution on the processing surface of the halted semiconductor wafer W, or supplies the developing solution on the processing surface of the halted semiconductor wafer W and cup 201 while traveling in the X direction. After the developing processing by the developing solution has proceeded for a predetermined time, the semiconductor wafer W is moved downward, placed on a spin chuck configured to be rotatable, and rotated to blow the developing solution. Then, the semiconductor wafer W is supplied with the rinse solution by the first processing liquid supply mechanism 202 inside the liquid processing apparatus and/or the processing liquid nozzle 205 that is the second processing liquid supply mechanism inside the liquid processing apparatus inside the liquid processing apparatus, and undergoes the processing.

In addition, each of the resist coater COT, antireflective film forming apparatus HB and development processing apparatus DEV described previously is provided with the spin chuck as a mount mechanism that holds the semiconductor wafer W in vacuum absorption to rotate. For a set value according to rotation of the spin chuck, a worker sets the value with an operation panel as an operation mechanism of the control mechanism of the apparatus. For setting in the case of the resist coater COT and/or antireflective film forming apparatus HB, it is configured that the rotation speed can be set at a predetermined range value (first speed range value), for example, at a predetermined speed value in the range of 0 or 10 to 4000 rpm, and that the precision can be set at a predetermined precision value (first speed precision value), for example, at ±1 rpm. Further, it is configured that the rotation acceleration can be set at a predetermined range value (first acceleration range value), for example, at a predetermined acceleration value in the range of 100 to 30000 rpm/s, and that the precision can be set at a predetermined precision value (first acceleration precision value), for example, at 100 rpm/s. Meanwhile, for setting in the case of the development processing apparatus DEV, it is configured that the rotation speed can be set at a predetermined range value (second speed range value narrower than the first speed range value and/or with the maximum value lower than the maximum value in the first speed range value), for example, at a predetermined speed value in the range of 0 or 10 to 3000 rpm, and that the precision can be set at a predetermined precision value (second speed precision value higher than the first speed precision value), for example, at ±0.5 rpm. Further, it is configured that the rotation acceleration can be set at a predetermined range value (second acceleration range value narrower than the first acceleration range value and/or with the maximum value lower than the maximum value in the first acceleration range value), for example, at a predetermined acceleration value in the range of 100 to 10000 rpm/s, and that the precision can be set at a predetermined precision value (second acceleration precision value equal to the first acceleration precision value), for example, at 100 rpm/s.

Moreover, the precision of the rotation acceleration to an instructed acceleration is determined to be predetermined precision, for example, ±7% in the case of the spin chuck of the resist coater COT and/or antireflective film forming apparatus HB, while being determined to be predetermined precision, for example, ±3% in the case of the spin chuck of the development processing apparatus DEV. Further, for monitoring according to the rotation of the spin chuck in the resist coater COT and development processing apparatus DEV, it is configured to enable each of a plurality of warning values to be set. For example, it is configured that when the speed is a predetermined value more than or equal to ±10% and less than ±20% of the set value, warning notification is made, and that when the speed is more than or equal to ±20% of the set speed, alarm notification is made while the control mechanism performs the operation of halting the spin chuck. In addition, it is assumed that the control mechanism does not halt the spin chuck in the case of warning notification. Further, for exhaust monitors in the resist coater COT and development processing apparatus DEV, the same or substantially same digital manometers are used, and configured to enable monitoring in a range of predetermined pressure values, for example, 0 to 500 Pa.

Described next is another embodiment in the substrate delivering/receiving stations 20 and 21 of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

As shown in FIG. 40, above the substrate delivering/receiving stations 20 and 21 is provided a gas flowing mechanism, for example, a plate member 223 set at a predetermined angle configured to flow the down-flow DF coming from above the apparatus to the side opposite to the liquid processing apparatus side, for example, the resist coater COT side, i.e. to the substrate carrying mechanism 10 side. This is because when the semiconductor wafer W is placed on the substrate delivering/receiving stations 20 and 21, the down-flow DF is prohibited from flowing downward by the semiconductor wafer W, and thus, is prevented from entering each processing apparatus side. It is thereby possible to suppress fluctuations in the flow of gas inside the apparatus, and to enhance the yield according to the substrate processing. In addition, as a matter of course, the plate member 223 may be provided with a predetermined communication hole, for example, a slit, punched hole and the like.

Described next is another embodiment in the delivering portion 4 and receiving portion 5 of the interface unit section IFU of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

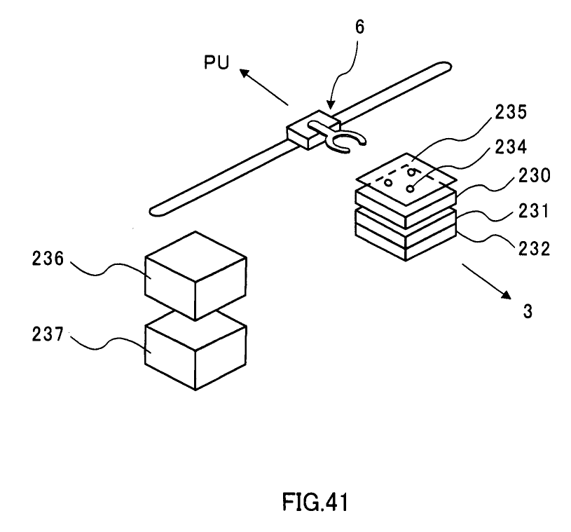

As shown in FIG. 41, the delivering portion 4 and receiving portion 5 are not provided separately, and have a delivering/receiving mechanism 230 with the functions as a delivering and receiving mechanism. In a position under the delivering/receiving mechanism 230 are provided a plurality of temperature adjustment sections, 231 and 232, stacked to set the semiconductor wafer W to a predetermined temperature. The temperature adjustment sections 231 and 232 have the function of adjusting the temperature of the semiconductor wafer W prior to the exposure processing that is not delivered to the exposure apparatus 3. Further, in a position above the delivering/receiving mechanism 230 is provided a waiting portion 235 provided with a plurality of support pins 234 to support the semiconductor wafer W in point contact from the backside of the semiconductor wafer W to put the semiconductor wafer W on standby after or before the temperature adjustment sections 231 and 232 adjust the temperature of the semiconductor wafer W, after the semiconductor wafer W is carried from the delivering/receiving mechanism 230, or before the semiconductor wafer W is carried to the delivering/receiving mechanism 230. Since the temperature adjustment sections 231 and 232 are provided in the position under the delivering/receiving mechanism 230, it is possible to promote stability of the temperature of the semiconductor wafer W that could be affected by the ambient temperature and the like while supplying the semiconductor wafer W with fluctuations in temperature suppressed to the exposure apparatus 3, and it is thereby possible to enhance the yield of the processing according to the semiconductor wafer W. Further, to the side of the delivering/receiving mechanism 230 of the interface unit section IFT, a plurality of cassettes, 236 and 237, is configured to enable an arrangement in the vertical direction as storage body configured to enable a plurality of semiconductor wafers W processed in the exposure apparatus 3 to be stored therein by the substrate carrying in/out mechanism 6. The cassettes 236 and 237 are configured to be carried in and out from outside the apparatus freely via a door not shown. Further, the cassettes 236 and 237 are configured to be carried in/out from outside the apparatus, and therefore, preferably disposed to the side, for example, to the right of the delivering/receiving mechanism 230 when viewed in the direction of the exposure apparatus 3 from the substrate carrying in/out mechanism 6. In addition, the example that the substrate carrying in/out mechanism 6 is self-propelled is described in the foregoing, but the substrate carrying in/out mechanism 6 may be formed of a carrying mechanism by non-self-propelled articulated robot that does not travel.

Described next is another embodiment in the cassette unit section CU of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

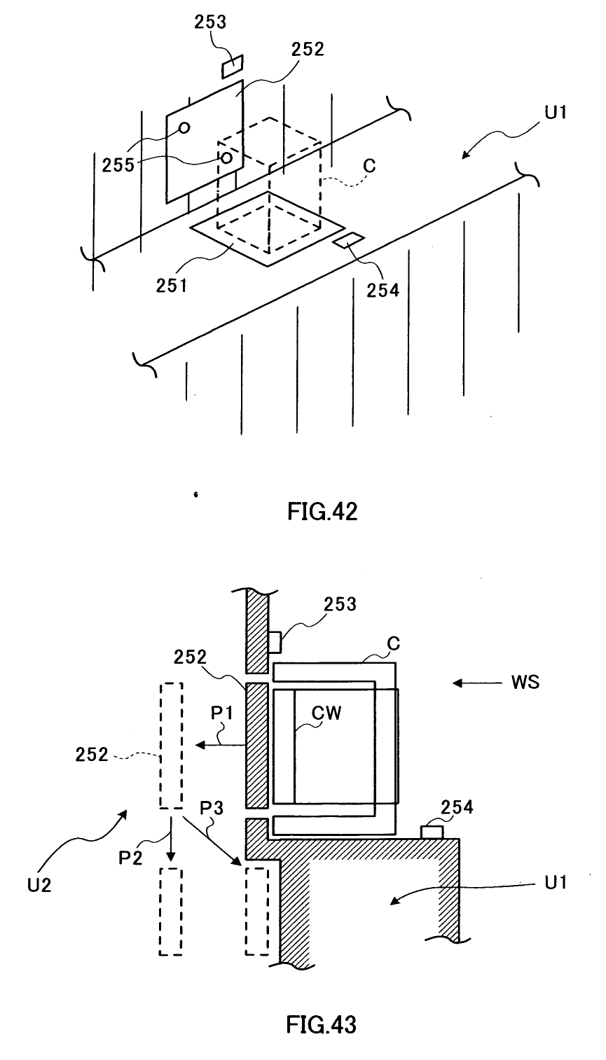

In the cassette unit section CU, as shown in FIGS. 42 and 43, a cassette is C carried into a placement portion 251 where a cassette C of the cassette mount section U1 is placed, in the work area direction WS by a worker or robot such as AGV and the like. When a worker carries the cassette C, a display mechanism 253 that determines whether the cassette is carried in by a worker or not is disposed at the back of the placement portion 251 of the cassette mount section U1 of the cassette unit section CU viewed in the work area direction WS, and in a position above an opening/closing door 252. The display mechanism 253 is configured to be able to display separately at least, for example, LOAD display indicating that the cassette is allowed to be carried in, and for example, UNLOAD display indicating that the cassette is allowed to be carried out, to the worker. The worker of the work area confirms the LOAD display, and then, places the cassette C in the placement portion 251. Then, the worker presses an operation mechanism, for example, switch 254 to notify the control mechanism of the apparatus that the cassette C is placed in the placement portion 251. The switch 254 is disposed on the front side of the placement portion 251 of the cassette mount section U1 of the cassette unit section CU viewed from the work area direction WS. When the switch 254 is pressed, the control mechanism of the apparatus recognizes the load instruction, and displays a message indicative of the recognition in the display mechanism 253. It is configured that this display enables the worker to judge that the apparatus recognizes the load. The worker is thereby capable of checking the working system appropriately and the like, and the stability of the apparatus can be improved.

Then, a cassette cover CW of the cassette C in the placement portion 251 is held in absorption by a coupling mechanism provided in the opening/closing door 252, for example, a plurality of holding portions 255 that holds the cover in vacuum absorption, and the opening/closing door 252 travels P1 horizontally once to the substrate carrying in/out mechanism section U2 side while holding the cover CW. Then, the opening/closing door 252 is configured to travel P2 vertically to a lower position or travel P2 vertically to a lower position to make a flow of the down-flow smooth, and be stored under the cassette mount section U1 or moved in the cassette mount section U1 direction. In addition, after the opening/closing door 252 travels P1 horizontally once to the substrate carrying in/out mechanism U2 side, the opening/closing door 252 may be configured to travel P3 to a storage position under the cassette mount section U1 or in a slanting downward direction to the cassette mount section U1 direction. In addition, the cassette C having the above-mentioned cassette cover CW is the so-called FOUP type of cassette, and in the case of using such a FOUP type of cassette, the pressure inside the substrate carrying in/out mechanism section U2 of the cassette unit section CU is set at a predetermined pressure that is lower than the pressure inside the process unit PU and higher than the pressure inside the cassette mount section U1 (clean room) of the cassette unit section CU, for example, at substantially 0.3 Pa (that is substantially the same as the pressure inside the interface unit section IFU). In addition, in the case of using an open cassette instead of FOUP type of cassette, a difference in pressure between the cassette mount section U1 and substrate carrying in/out mechanism section U2 of the cassette unit section CU is smaller than in using FOUP type of cassette, and the pressure inside the substrate carrying in/out mechanism section U2 is configured to be set at a predetermined pressure, for example, at a pressure of substantially 0.1 Pa or less. By this means, it is possible to maintain the degree of cleanness and the like in the atmosphere of the work system, and to enhance the yield of the semiconductor wafers W.

Described next is another embodiment in the liquid processing unit of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

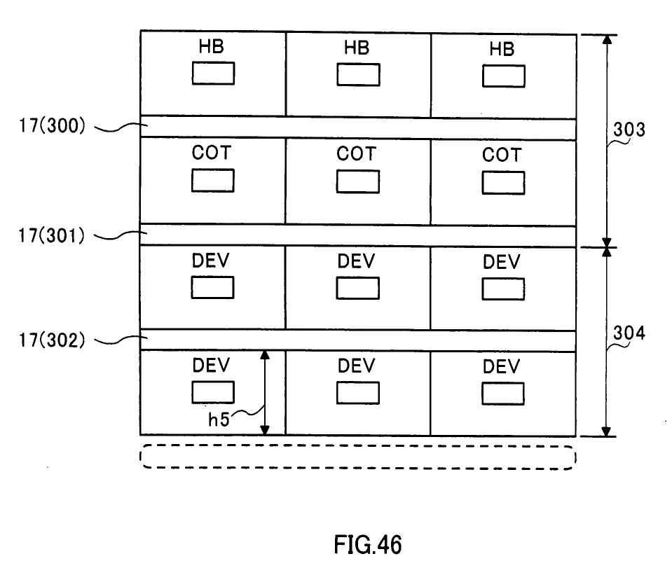

In the liquid processing unit section, as shown in FIG. 46, in the lower position are disposed development processing apparatus DEV blocks, stacked in a plurality of, for example, two stages, comprised of a plurality of development processing apparatuses DEV arranged in a lateral direction, above the DEV blocks is disposed a coater COT block comprised of a plurality of coaters COT arranged in a lateral direction, and above the COT block is stacked and disposed an antireflective film coater HB block comprised of a plurality of antireflective film coaters arranged in a lateral direction to form an under coating of the resist film and/or an antireflective film as an over coating of the resist film. Further, the antireflective film coater HB block has the base 17 (300) provided with the substrate carrying mechanism 15 that carries the semiconductor wafer W to/from each of the antireflective film coaters HB. The coater COT block has the base 17 (301) provided with the substrate carrying mechanism 15 that carries the semiconductor wafer W to/from each of the coaters COT. The development processing apparatus DEV blocks have the base 17 (302) provided with the substrate carrying mechanism 15 that carries the semiconductor wafer W to/from each of the development processing apparatuses DEV. The base 17 (302) is different from the fixed base 17 provided with the substrate carrying mechanism 15 in the antireflective film coater HB block and/or the coater COT block, configured to travel freely vertically between h5 in the figure, and thus configured to enable a single base 17 (302) to support a plurality of development processing apparatus DEV blocks as blocks comprised of a plurality of stacked processing apparatuses for the same processing.

By such a configuration, when the same processing blocks are stacked, the base 17 (302) is made movable vertically, and it is thus possible to decrease the number of bases 17 (302), and to reduce the size or cost of the apparatus. In addition, as a home position of the base 17 (302), a solid-line position of the base 17 (302) in the figure is preferable as a middle position of stacked same processing blocks, but a dotted-line position of the base 17 (302) is also available naturally as a lower position of stacked same processing blocks. Further, in consideration of the relationship between fixing and traveling of the bases 17, a vertical distance 303 between the antireflective film coater HB block and the coater COT block is preferably set at a distance longer or larger than a vertical distance 304 of a plurality of development processing apparatus DEV blocks. Furthermore, the substrate delivering/receiving stations 20 and 21 may be provided on each of bases 17, or configured to travel vertically to be able to access all the bases 17. Alternately, it is naturally configured that the substrate delivering/receiving stations 20 and 21 are moved vertically to support each of bases 17 of the antireflective film coater HB block and/or the coater COT block, and that dedicated substrate delivering/receiving stations 20 and 21 are fixed to the base 17 of the development processing apparatus DEV blocks to be configured to travel vertically together with the base 17. In addition, from the relationship of the processing between the processing apparatuses, it is preferable that a plurality of stages of development processing apparatus DEV blocks are provided in the vertical direction, a stage of coater COT block is stacked above the DEV blocks, and that a stage of antireflective film coater HB block is disposed above the COT block.

Described next is another embodiment according to the configuration in the liquid processing unit section and heater section of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

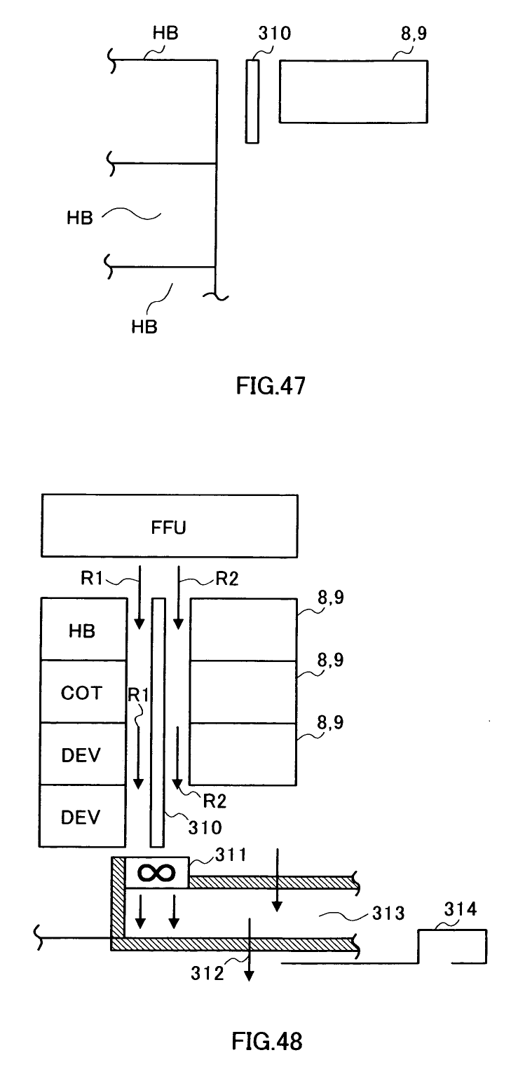

As shown in FIGS. 47 and 48, between the liquid processing unit sections HB, COT, DEV and the heater sections 8, 9, HPB1, HPB2 is disposed a shield plate 310 as a thermal interference suppressing mechanism to suppress the effect of heat of the heater sections on the liquid processing unit sections. By the shield plate 310, it is configured that the down-flow with adjusted at least temperature and/or moisture of a predetermined value supplied from a filter FFU disposed above the apparatuses is divided into a path R1 on the liquid processing unit section side and a path R2 on the heater section side to flow. In addition, the down-flow with adjusted at least temperature and/or moisture includes air obtained by cleaning air with adjusted at least temperature and/or moisture by a filter. Alternately, the down-flow may be caused to flow independently inside the processing apparatuses. Further, the direction of a flow of the down-flow may be changed according to the order in which the processing apparatuses are stacked. For example, the down-flow may be caused to flow from the liquid processing unit section side to the heater section side. Further, in a position under the shield sheet 310 is provided an exhaust mechanism 311 provided with a fan that forces the atmosphere gas from both the path R1 on the liquid processing unit section side and path R2 on the heater section side to flow downward. The atmosphere gas exhausted by the exhaust mechanism 311 once flows into a communication chamber 312 as a space portion, and is configured to be collectively discharged outside the apparatus from the communication chamber 312 by an exhaust mechanism 314. In addition, it is configured that the atmosphere gas is introduced to the communication chamber 312 from the arrangement space of the arrangement region of, for example, the substrate carrying mechanism 10 and like and/or arrangement region of the heat treatment section and the like inside the apparatus, not through the exhaust mechanism 311 but through communication holes, for example, slits and/or punched holes and the like provided in the communication chamber 312. In such a configuration, it is possible to suppress the effect of the heater section on the liquid processing unit section and/or the effect of dust such as particles generated from the substrate carrying mechanism 10 and the like on the liquid processing unit section, and it is thereby possible to enhance the yield of the processing of the semiconductor wafer W in the liquid processing unit section. In addition, for an arrangement of the shield plate 310 between the liquid processing unit section and heater section, it is certainly preferable that the shield plate 310 is disposed on the side where the semiconductor wafer W is carried in/out in the liquid processing unit section, but the shield plate 310 can be disposed between the liquid processing unit section and heater section on the side where the semiconductor wafer W is not carried in/out in the liquid processing unit section.

Described next is another embodiment according to the configuration in the liquid processing unit section and heater section of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

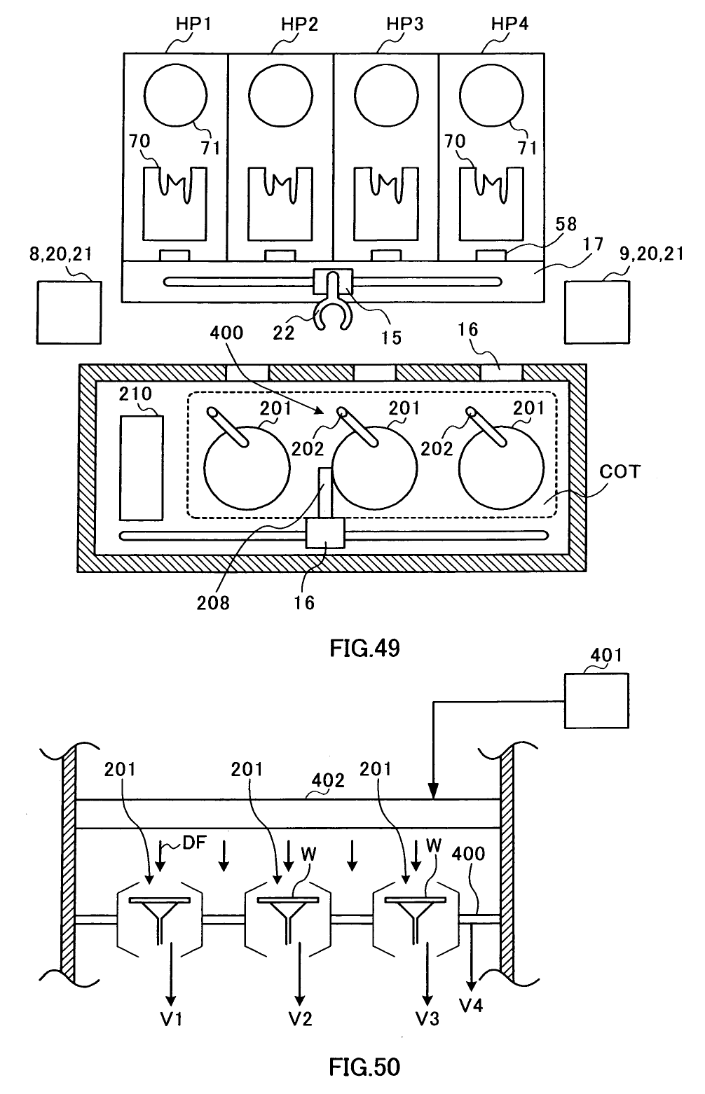

In the liquid processing unit section and heater section, as shown in FIGS. 49 and 50, as the heater section, a plurality of heaters, HP1 to HP4, is provided in the horizontal direction (each of the heaters HP1 to HP4 is stacked to form a heater HP), and the substrate carrying mechanism 15 is configured to be disposed on the heater side. The base 17 of the substrate carrying mechanism 15 is configured to be movable in the vertical direction and in the horizontal direction as an XY stage, a plurality of arms 22 of the substrate carrying mechanism is stacked and provided, and each arm is configured to be rotatable and expandable. It is configured that the arm 22 enables the semiconductor W to be carried to/from the liquid processing unit section and/or heater section. In addition, as described above, the substrate carrying mechanism 15 may be disposed for each of stacked blocks in the liquid processing unit section. Further, when a plurality of development processing apparatus DEV blocks is stacked and provided in the liquid processing unit section, as described previously, one substrate carrying mechanism 15 may be provided to be shared between the blocks. In the liquid processing unit section, for example, in the coater COT block, cups 201 inside the coater COT block are arranged in the horizontal direction, the atmosphere between the cups is not blocked completely, a flowing mechanism 402 is disposed that flows a gas with the controlled temperature and moisture introduced from a gas supply source 401 existing above to the direction of cups 201 inside the coater COT block (formation of the down-flow DF), and the liquid processing unit section is thus configured that the pressure inside the section is higher than the pressure outside the section.

Further, a placement region 400 of each cup 201 is present in a position lower than the flowing mechanism 402, and configured to enable the gas therein to be exhausted downward (V4 in the figure), while each of a plurality of cups 201 is configured to be evacuated freely independently of one another (V1, V2, V3 in the figure). When the semiconductor wafer W is rotated and supplied with the resist solution, at least the corresponding cup 201 is configured to be evacuated. The other cups 201 that do not perform the processing a reconfigured to reduce an exhaust amount than in performing the processing or halt exhaust. It is preferable that the total exhaust amount of V1+V2+V3+V4 is kept constant by the control mechanism. The reason of keeping the total exhaust amount constant is because when the pressure inside the liquid processing unit section varies, fluctuations occur in formation of the resist film. Further, it is considered varying the supply amount of the down-flow DF from the flowing mechanism 402, but the system control is complicated and the time is required for the supply amount to be constant, and it is necessary to prevent the pressure inside the liquid processing unit section from being unstable. In addition, as described previously, the substrate delivering/receiving stations 20 and 21 may be configured to be fixed, movable vertically, or movable with the substrate carrying mechanism 15, as described above. Further, the substrate carrying mechanism 15 may be configured to be able to deliver and receive the semiconductor wafer W directly to/from the substrate delivering/receiving portions 8 and 9. Furthermore, although not shown, at least one carrying mechanism may be provided to carry the semiconductor wafer W between the substrate delivering/receiving portions 8 and 9 and substrate delivering/receiving stations 20 and 21. Still furthermore, the substrate delivering/receiving stations 20 and 21 can be moved up and down independently of each other.

Described next is another embodiment according to the configuration in heater section of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

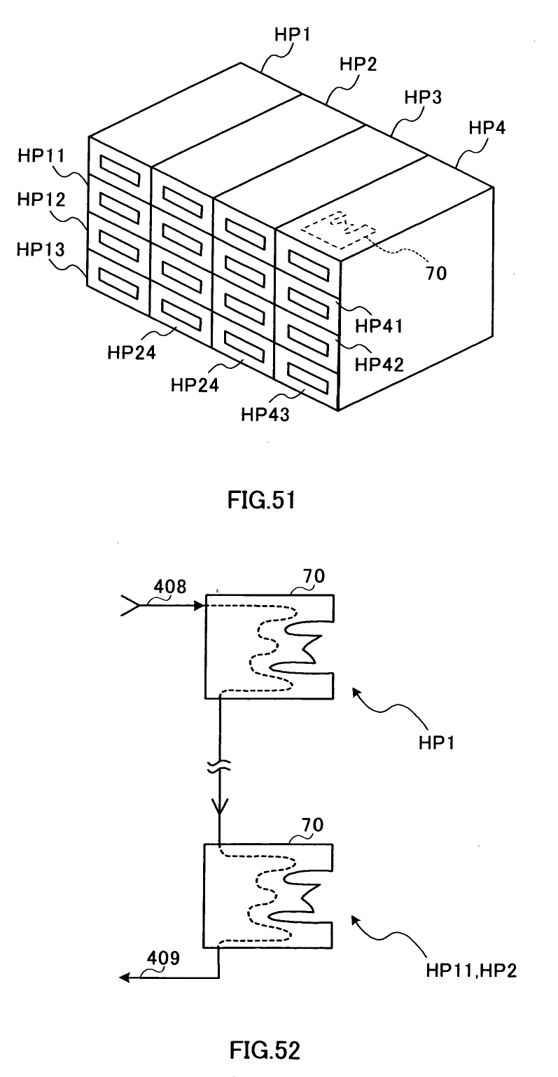

In the heater section, as shown in FIGS. 51 and 52, the heater sections HP1, HP2, HP3 and HP4 are disposed together in the horizontal direction, and under the heater sections HP1, HP2, HP3 and HP4 are stacked and disposed are a plurality of heater sections in the vertical direction. For example, under the heater section HP1, heater sections HP11, HP12 and HP13 are disposed. It is configured that cooling water with a predetermined temperature, for example, substantially 23° C. flows inside the temperature adjustment mechanism 70 used in each of the heater sections. The cooling water is configured to be shared among the heater sections HP1, HP2, HP3 and HP4 arranged in the horizontal direction or heater sections HP1, HP11, HP12 and HP13 arranged in the vertical direction as a block and flow inside the control adjustment mechanism 70. Accordingly, a supply of the cooling water disposed outside the apparatuses is configured to supply the water to a plurality of sections as a block unit. By such a configuration, it is possible to decrease the number of pipes for cooling water and to reduce the size of the system. Further, the pipes can be managed in a block unit, and the maintenance to the block is made easy. Furthermore, it is possible for the control mechanism to control the temperature of the cooling water with efficiency.

Described next is another embodiment according to the configuration in the liquid processing unit section and heater section of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

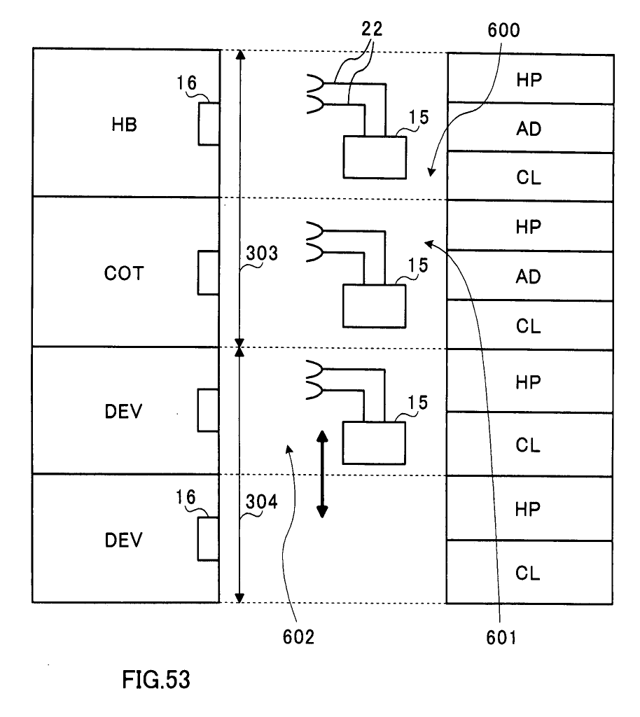

As shown in FIG. 53, in the liquid processing unit section and heater section, the number of stacks of the heater section is set corresponding to the height distance of the liquid processing unit section. In other words, when the vertical distance 303 between the antireflective film coater HB block and the coater COT block is set at a distance longer or larger than a vertical distance 304 of a plurality of development processing apparatus DEV blocks, the number of stacks of the heaters corresponding to the antireflective film coater HB block and the coater COT block is preferably larger than the number of stacks of the heaters corresponding to development processing apparatus DEV blocks. In the case of this embodiment, the number of arranged stacks of the heaters corresponding to the antireflective film coater HB block and the coater COT block is three, while the number of stacks of the heaters corresponding to development processing apparatus DEV blocks is two. Further, for configurations of the heaters corresponding to the antireflective film coater HB block and the coater COT block, in each configuration, from the above, a heater HP that treats the semiconductor wafer W with predetermined heat, for example, the temperature of 100° C. or more is disposed, under the heater HP is disposed a hydrophobic processing apparatus AD that adds predetermined heat to the semiconductor wafer W to perform the hydrophobic processing, and under the apparatus AD is disposed a temperature adjustment apparatus CL that adjusts the temperature of the semiconductor wafer W treated in the heater HP and/or hydrophobic processing apparatus AD and the like to, for example, the same temperature as the ambient temperature inside the apparatus, for example, substantially 23° C. In addition, the heater HP and hydrophobic processing apparatus can be switched in upper and lower positions to be disposed.

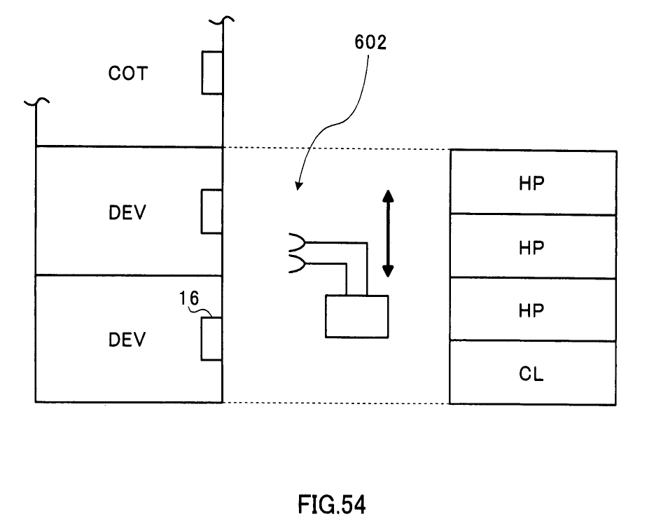

In each of the heaters corresponding to the development processing apparatus DEV block, a heater HP is disposed that treats the semiconductor wafer W with predetermined heat, for example, the temperature of 100° C. or more before and/or after the semiconductor wafer W is processed in the development processing apparatus DEV, and under the apparatus HP is disposed a temperature adjustment apparatus CL that adjusts the temperature of the semiconductor wafer W treated in the heater HP and the like to, for example, the same temperature as the ambient temperature inside the apparatus, for example, substantially 23° C. Further, in each of a zone 600 of the antireflective film coater HB block and a zone 601 of the coater COT block, provided is the substrate carrying mechanism 15 configured to be able to carry the semiconductor wafer W to/from the apparatuses in the zone. A zone 602 of the development processing apparatus DEV block may have the substrate carrying mechanism 15 for each horizontal block to be used independently, but in this embodiment, is configured to support by one mechanism 15, as described previously. When the substrate carrying mechanism 15 is thus shared, unlike the order of, from the bottom, the temperature adjustment apparatus CL, heater HP, temperature adjustment apparatus CL, and heater HP as shown in FIG. 53, it is preferable that as shown in FIG. 54, the temperature adjustment apparatus CL is disposed under the heaters HP in the zone 602 such as the order of, from the bottom, the temperature adjustment apparatus CL, heater HP, heater HP and heater HP so as to consider suppression of problems caused by the effect of heat. Further, it is preferable that dotted-line portions between the carrying mechanisms in the figure are sealed to provide each of the carrying mechanisms with the atmosphere of an independent airtight space portion, and that a gas with adjusted at least temperature and/or moisture of a predetermined value is introduced to each space portion. In addition, in this case, the introduced gas with adjusted at least temperature and/or moisture includes air obtained by cleaning air with adjusted at least temperature and/or moisture by a filter. Further, it is preferable that the jet direction of the gas is configured so that the gas flows from the liquid processing unit section side to the heater section side. In addition, it is preferable that the hydrophobic processing apparatus AD is only present in each of the zone 600 of the antireflective film coater HB block and the zone 601 of the coater COT block, without being disposed in the zone 602 of the development processing apparatus DEV block.

Described next is another embodiment according to the configuration in the heater section of this embodiment. In addition, the same components as in the above-mentioned embodiments are assigned the same reference numerals to omit specific descriptions. Naturally, the invention according to this embodiment is capable of being used in a combination with another embodiment, and is not limited to this embodiment.

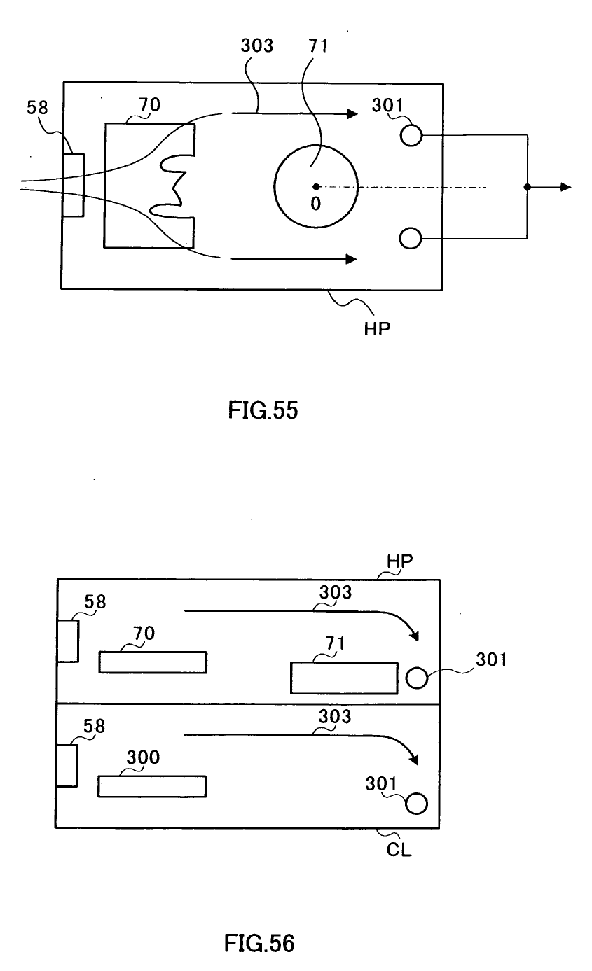

In the heater section, as shown in FIG. 55, the atmosphere gas from a carrying inlet/outlet 58 of the semiconductor wafer W in the heater HP is configured to flow 303 in the direction of the heating mechanism 71 from the temperature adjustment mechanism 70 side. A plurality of, for example, two exhaust holes 301 of the heater HP are disposed at opposite ends between which is the line extending from a center position 0 of the temperature adjustment mechanism 70 on the side opposite to the temperature adjustment mechanism 70 of the heating processing mechanism 71. In addition, as the arrangement positions, the exhaust holes 300 are spaced substantially the same distance apart from the line of the center position 0. Further, as shown in FIG. 56, in the temperature adjustment apparatus CL disposed above and/or under the heater HP, a temperature adjustment plate 300 is disposed to adjust the temperature, and has the same depth as the depth of the heater HP. The flow 303 inside the temperature adjustment apparatus CL is made in the same direction as the flow 303 inside the heater HP. Further, exhaust holes 301 of the temperature adjustment apparatus CL are also disposed in the same positions as those of the exhaust holes 301 of the heater HP. In addition, a plurality of exhaust holes 301 is provided, but can be an exhaust hole in the shape of a linear slit perpendicular to the arrangement direction of the temperature adjustment mechanism 70 and heating mechanism 71.

The semiconductor wafer is used as the above-mentioned substrate and described, but the invention is not limited thereto. For example, a glass substrate such as an LCD substrate and the like may be used, and further, substrates of disks such as CD and the like may be used. The liquid processing is not limited to development and coating, and the invention is applicable to a cleaning apparatus and the like, and is not limited particularly in methods and apparatuses using the processing liquid. Further, the invention is applicable to a plurality of heaters without being limited to the liquid processing apparatus. Furthermore, the technique of the invention is applicable to apparatuses where one liquid processing apparatus is replaced with an inspection apparatus and the like.

The present invention has advantageous effects of facilitating additional installation of processing apparatuses such as the liquid processing apparatus and the like, improving throughput in the processing according to the apparatuses while facilitating control of the processing time in each processing apparatus, and thereby improving the yield according to the processing of the processing target substrate, mainly by a self-propelled carrying mechanism configured to enable the processing target substrate to be carried to/from each of at least two linearly arranged liquid processing apparatuses and to be movable in parallel with an arrangement direction of the liquid processing apparatuses, a substrate delivering/receiving mechanism configured to enable the processing target substrate to be delivered and received to/from the self-propelled carrying mechanism, and a non-self-propelled carrying mechanism configured to enable the processing target substrate to be delivered and received to/from the substrate delivering/receiving mechanism.

The present invention is applicable to a substrate processing apparatus, substrate processing method and substrate manufacturing method in a semiconductor manufacturing apparatus and the like.

1. A substrate processing apparatus having a liquid processing apparatus group comprised of a development processing apparatus where a plurality of processing cups each to supply a developing solution to a processing target substrate to process is disposed in one direction on the same space, and a resist processing apparatus, disposed above the development processing apparatus, where a plurality of processing cups each to supply a resist solution to the processing target substrate to process is disposed in one direction on the same space or an antireflective film processing apparatus, disposed above the development processing apparatus, where a plurality of processing cups each to supply an antireflective film solution to the processing target substrate to process is disposed in one direction on the same space, comprising:
a first carrying mechanism that substantially carries the processing target substrate to each of the processing cups of the development processing apparatus via an opening portion for each of the processing cups provided in the development processing apparatus;
a second carrying mechanism that substantially carries the processing target substrate to each of the processing cups of the resist processing apparatus or the antireflective film processing apparatus via an opening portion for each of the processing cups provided in the resist processing apparatus or the antireflective film processing apparatus;
a first rotation mechanism that is provided in each of the plurality of processing cups in the development processing apparatus and that rotates the processing target substrate;
a second rotation mechanism that is provided in each of the plurality of processing cups in the resist processing apparatus or the antireflective film processing apparatus and that rotates the processing target substrate; and
a control mechanism which sets a rotation speed of the first rotation mechanism at a predetermined value in a range narrower than a range of a rotation speed of the second rotation mechanism, and/or sets a rotation acceleration of the first rotation mechanism at a predetermined value in a range narrower than a range of a rotation acceleration of the second rotation mechanism.

2. The substrate processing apparatus according to claim 1, further comprising:
a first gas supply mechanism that is provided in the development processing apparatus and that supplies a gas with adjusted at least temperature and moisture collectively to the plurality of processing cups in the development processing apparatus; and
a second gas supply mechanism that is provided in the resist processing apparatus or the antireflective film processing apparatus and that supplies a gas with adjusted at least temperature and moisture collectively to the plurality of processing cups in the resist processing apparatus or the antireflective film processing apparatus.

3. The substrate processing apparatus according to claim 1, wherein the second carrying mechanism is stacked and disposed above the first carrying mechanism.

4. The substrate processing apparatus according to claim 1, further comprising:
a heat treatment apparatus group comprised of a plurality of stacked heat treatment apparatuses which are provided on the side opposite to the development processing apparatus and the resist processing apparatus or the antireflective film processing apparatus for the first carrying mechanism and the second carrying mechanism, and which perform heat treatment on the processing target substrate;
a first heat treatment apparatus group disposed in a carrying region of the first carrying mechanism inside the heat treatment apparatus group; and
a second heat treatment apparatus group disposed in a carrying region of the second carrying mechanism inside the heat treatment apparatus group.

5. The substrate processing apparatus according to claim 1, wherein the control mechanism is configured to enable a precision value of the rotation speed of the first rotation mechanism to be set at a precision value higher than a precision value of the rotation speed of the second rotation mechanism, and/or to enable a precision value of the rotation acceleration of the first rotation mechanism to be set at a precision value substantially equal to a precision value of the rotation acceleration of the second rotation mechanism.

6. The substrate processing apparatus according to claim 1, wherein the control mechanism is configured to enable a maximum value of the rotation speed of the first rotation mechanism to be set at a maximum value lower than a maximum value of the rotation speed of the second rotation mechanism.

7. The substrate processing apparatus according to claim 4, where between the heat treatment apparatus group and the liquid processing apparatus group is disposed a dividing mechanism that divides a gas with adjusted at least temperature and moisture supplied from an upper portion into the gas flowing downward along the liquid processing apparatus group and the gas flowing downward along the heat treatment apparatus group.

8. The substrate processing apparatus according to claim 1, wherein another development processing apparatus with the substantially same configuration as that of the development processing apparatus is disposed in a position under the development processing apparatus in a stacked manner, and the first carrying mechanism is configured to also carry the processing target substrate to the another development processing apparatus.

9. The substrate processing apparatus according to claim 4, wherein each of the first heat treatment apparatus group and the second heat treatment apparatus group has therein at least one heat treatment apparatus having a movable temperature adjustment mechanism, and a heating processing mechanism that receives the processing target substrate via the temperature adjustment mechanism to heat the processing target substrate at a predetermined temperature.

10. The substrate processing apparatus according to claim 9, wherein the heat treatment apparatus has a carrying in/out opening for the processing target substrate from the first carrying mechanism or the second carrying mechanism, the temperature adjustment mechanism and the heating processing mechanism are disposed substantially at the back of the apparatus from the carrying in/out opening, and an exhaust opening to exhaust a gas inside a plurality of heat treatment apparatuses is provided at the back of the heating processing mechanism.

11. The substrate processing apparatus according to claim 1, wherein the development processing apparatus has an exhaust mechanism that exhausts a gas from inside each of the processing cups inside the development processing apparatus and from a region outside the each of the processing cups, and the resist processing apparatus or the antireflective film processing apparatus has an exhaust mechanism that exhausts a gas from inside each of the processing cups inside the resist processing apparatus or the antireflective film processing apparatus and from a region outside the each of the processing cups.

12. The substrate processing apparatus according to claim 1, wherein the development processing apparatus has an exhaust mechanism that is configured to independently perform or halt exhaust of a gas from inside each of the processing cups in the development processing apparatus, while exhausting the gas from a region outside the each of the processing cups, and the resist processing apparatus or the antireflective film processing apparatus has an exhaust mechanism that exhausts a gas from inside each of the processing cups in the resist processing apparatus or the antireflective film processing apparatus and from a region outside the each of the processing cups.

13. The substrate processing apparatus according to claim 11, wherein in exhaust by the exhaust mechanism of the development processing apparatus and exhaust by the exhaust mechanism of the resist processing apparatus, the gas is exhausted with an exhaust amount such that pressures inside the development processing apparatus and the resist processing apparatus or the antireflective film processing apparatus are not lower than pressures of atmosphere gases in regions where the first carrying mechanism and the second carrying mechanism are disposed, respectively.

14. The substrate processing apparatus according to claim 1, wherein a processing liquid supply mechanism that supplies a processing liquid to the processing target substrate independently in each of the processing cups inside the development processing apparatus is disposed in the development processing apparatus, and a processing liquid supply mechanism that supplies a processing liquid to the processing target substrate independently in each of the processing cups inside the resist processing apparatus or the antireflective film processing apparatus is disposed in the resist processing apparatus or the antireflective film processing apparatus.

15. The substrate processing apparatus according to claim 12, wherein a total exhaust amount of exhaust by the exhaust mechanism of the development processing apparatus is kept constant, while a total exhaust amount of exhaust by the exhaust mechanism of the resist processing apparatus or the antireflective film processing apparatus is also kept constant.

16. The substrate processing apparatus according to claim 9, wherein a plurality of heat treatment apparatuses is disposed or stacked in the horizontal direction or vertical direction, and a common liquid is supplied to temperature adjustment mechanisms of at least two heat treatment apparatuses among the plurality of heat treatment apparatuses.

17. The substrate processing apparatus according to claim 11, wherein exhaust is configured so that the gas exhausted from inside each of the processing cups and the region outside the each of the processing cups inside the resist processing apparatus or the antireflective film processing apparatus is collectively discharged outside the resist processing apparatus or the antireflective film processing apparatus, the gas exhausted from inside each of the processing cups and the region outside the each of the processing cups inside the development processing apparatus is collectively discharged outside the development processing apparatus, the gas exhausted from the resist processing apparatus or the antireflective film processing apparatus is horizontally discharged in a region between the resist processing apparatus or the antireflective film processing apparatus and the development processing apparatus, and that the gas exhausted from the development processing apparatus is horizontally discharged in a region between the development processing apparatus and another liquid processing apparatus.

18. A substrate processing method comprising:
rotating a processing target substrate by a first rotation mechanism that is provided in each of a plurality of processing cup mechanisms inside a development processing apparatus and that rotates the processing target substrate, and performing development on an exposed resist on a processing surface of the processing target substrate;
rotating the processing target substrate by a second rotation mechanism that is provided in each of a plurality of processing cup mechanisms inside a resist processing apparatus or an antireflective film processing apparatus and that rotates the processing target substrate, and supplying a processing liquid to the processing target substrate inside a processing cup to coat a resist solution or an antireflective film solution on the processing surface of the processing target substrate; and
beforehand setting a rotation speed of the first rotation mechanism at a predetermined value in a range narrower than a range of a rotation speed of the second rotation mechanism, and/or setting a rotation acceleration of the first rotation mechanism at a predetermined value in a range narrower than a range of a rotation acceleration of the second rotation mechanism.

19. The substrate processing method according to claim 18, wherein a gas with adjusted at least temperature and moisture is collectively supplied to the plurality of processing cups inside the development processing apparatus in the development processing apparatus, and a gas with adjusted at least temperature and moisture is collectively supplied to the plurality of processing cups inside the resist processing apparatus or the antireflective film processing apparatus in the resist processing apparatus or the antireflective film processing apparatus.

20. The substrate processing method according to claim 18, wherein a first carrying mechanism carries the processing target substrate to the plurality of processing cup mechanisms inside the development processing apparatus, and a second carrying mechanism different from the first carrying mechanism carries the processing target substrate to the plurality of processing cup mechanisms inside the resist processing apparatus or the antireflective film processing apparatus.

21. The substrate processing method according to claim 20, wherein the first carrying mechanism and the second carrying mechanism respectively carry the processing target substrate to a heat treatment apparatus inside a first heat treatment apparatus group disposed in a carrying region of the first carrying mechanism in a heat treatment apparatus group and to a heat treatment apparatus inside a second heat treatment apparatus group disposed in a carrying region of the second carrying mechanism in the heat treatment apparatus group comprised of a plurality of stacked heat treatment apparatuses which are provided on the side opposite to the development processing apparatus and the resist processing apparatus or the antireflective film processing apparatus, and which perform heat treatment on the processing target substrate.

22. The substrate processing method according to claim 18, wherein a precision value of the rotation speed of the first rotation mechanism is set in a range of the precision value higher than a precision value of the rotation speed of the second rotation mechanism, and/or a precision value of the rotation acceleration of the first rotation mechanism is set at a precision value substantially equal to a precision value of the rotation acceleration of the second rotation mechanism.

23. The substrate processing method according to claim 18, wherein a maximum value of the rotation speed of the first rotation mechanism is set in a range of maximum values lower than a maximum value of the rotation speed of the second rotation mechanism.

24. The substrate processing method according to claim 21, wherein in between the heat treatment apparatus group and the liquid processing apparatus group having the development processing apparatus and the resist processing apparatus or the antireflective film processing apparatus, a gas with adjusted at least temperature and moisture supplied from an upper portion is divided into the gas flowing downward along the liquid processing apparatus group and the gas flowing downward along the heat treatment apparatus group.

25. The substrate processing method according to claim 21, wherein each of the first heat treatment apparatus group and the second heat treatment apparatus group has therein a heat treatment apparatus having a movable temperature adjustment mechanism, and a heating processing mechanism that receives the processing target substrate via the temperature adjustment mechanism to heat the processing target substrate at a predetermined temperature, and a current of gas is generated inside the heat treatment apparatus to flow from the temperature adjustment mechanism side to the heating processing mechanism.

26. The substrate processing method according to claim 18, wherein a gas is exhausted from inside each of the processing cups inside the development processing apparatus and from a region outside the each of the processing cups in the development processing apparatus, and a gas is exhausted from inside each of the processing cups inside the resist processing apparatus or the antireflective film processing apparatus and from a region outside the each of the processing cups in the resist processing apparatus or the antireflective film processing apparatus.

27. The substrate processing method according to claim 18, wherein for the processing cups inside the development processing apparatus, selection between halt or operation of exhaust of a gas from inside each of the processing cups is performed independently of one another, and the gas is exhausted from inside the each of the processing cups and a region outside the each of the processing cups, while in the resist processing apparatus or the antireflective film processing apparatus, a gas is exhausted from inside each of the processing cups and a region outside the each of the processing cups.

28. The substrate processing method according to claim 21, wherein in exhaust by an exhaust mechanism of the development processing apparatus and exhaust by an exhaust mechanism of the resist processing apparatus or the antireflective film processing apparatus, a gas is exhausted with an exhaust amount such that pressures inside the development processing apparatus and the resist processing apparatus or the antireflective film processing apparatus are not lower than pressures of atmosphere gases in regions where the first carrying mechanism and the second carrying mechanism are disposed, respectively.

29. The substrate processing method according to claim 18, wherein in the resist processing apparatus or the antireflective film processing apparatus, a single processing liquid supply mechanism supplies a processing liquid to the processing target substrate in each of the processing cups inside the resist processing apparatus or the antireflective film processing apparatus.

30. The substrate processing method according to claim 27, wherein a total exhaust amount of exhaust in the development processing apparatus is kept constant, while a total exhaust amount of exhaust in the resist processing apparatus is also kept constant.

31. The substrate processing method according to claim 25, wherein a common liquid is supplied to the temperature adjustment mechanism.

32. The substrate processing method according to claim 27, wherein the gas exhausted from inside each of the processing cups and the region outside the each of the processing cups inside the resist processing apparatus or the antireflective film processing apparatus is collectively discharged outside the resist processing apparatus or the antireflective film processing apparatus, while being horizontally discharged in a region between the resist processing apparatus or the antireflective film processing apparatus and the development processing apparatus.

33. A substrate processing method comprising:
performing development on an exposed resist on a processing surface of a processing target substrate, while halting or operating exhaust in a predetermined processing cup mechanism of a plurality of processing cup mechanisms inside a development processing apparatus, and exhausting a gas from regions except regions of the plurality of processing cup mechanism inside the development processing apparatus;
supplying a processing liquid to the processing target substrate inside a predetermined processing cup with a same processing liquid supply mechanism, thereby supplying a resist solution or an antireflective film solution to the processing surface of the development processing apparatus, while exhausting a gas from inside the processing cup of a predetermined processing cup mechanism of a plurality of processing cup mechanisms in a resist processing apparatus or an antireflective film processing apparatus, and further exhausting a gas from regions except regions of the plurality of processing cup mechanisms inside the resist processing apparatus or the antireflective film processing apparatus;
supplying a same gas with adjusted at least temperature and moisture concurrently to the plurality of processing cup mechanisms inside the development processing apparatus;
supplying a same gas with adjusted at least temperature and moisture concurrently to the plurality of processing cup mechanisms inside the resist processing apparatus or the antireflective film processing apparatus; and
keeping a total exhaust amount from the development processing apparatus constant irrespective of halt or operation of the exhaust from inside a processing cup of the predetermined processing cup mechanism of the plurality of processing cup mechanisms inside the development processing apparatus.

34. The substrate processing method according to claim 33, wherein each of the plurality of processing cup mechanism inside the development processing apparatus has a first rotation mechanism that rotates the processing target substrate, and each of the plurality of processing cup mechanism inside the resist processing apparatus or the antireflective film processing apparatus has a second rotation mechanism that rotates the processing target substrate, while a rotation speed of the first rotation mechanism is beforehand set at a predetermined value in a range narrower than a range of a rotation speed of the second rotation mechanism, and/or a rotation acceleration of the first rotation mechanism is beforehand set at a predetermined value in a range narrower than a range of a rotation acceleration of the second rotation mechanism.

35. The substrate processing method according to claim 33, wherein a first carrying mechanism carries the processing target substrate to the plurality of processing cup mechanisms inside the development processing apparatus, and a second carrying mechanism different from the first carrying mechanism carries the processing target substrate to the plurality of processing cup mechanisms inside the resist processing apparatus or the antireflective film processing apparatus.

36. The substrate processing method according to claim 35, wherein the first carrying mechanism and the second carrying mechanism respectively carry the processing target substrate to a heat treatment apparatus inside a first heat treatment apparatus group disposed in a carrying region of the first carrying mechanism in a heat treatment apparatus group and to a heat treatment apparatus inside a second heat treatment apparatus group disposed in a carrying region of the second carrying mechanism in the heat treatment apparatus group comprised of a plurality of stacked heat treatment apparatuses which are provided on the side opposite to the development processing apparatus and resist processing apparatus or the antireflective film processing apparatus, and which perform heat treatment on the processing target substrate.

37. The substrate processing method according to claim 34, wherein a precision value of the rotation speed of the first rotation mechanism is set in a range of the precision value higher than a precision value of the rotation speed of the second rotation mechanism, and/or a precision value of the rotation acceleration of the first rotation mechanism is set at a precision value substantially equal to a precision value of the rotation acceleration of the second rotation mechanism.

38. The substrate processing method according to claim 34, wherein a maximum value of the rotation speed of the first rotation mechanism is set in a range of the maximum value lower than a maximum value of the rotation speed of the second rotation mechanism.

39. The substrate processing method according to claim 36, wherein in between the heat treatment apparatus group and the liquid processing apparatus group having the development processing apparatus and the resist processing apparatus or the antireflective film processing apparatus, a gas with adjusted at least temperature and moisture supplied from an upper portion is divided into the gas flowing downward along the liquid processing apparatus group and the gas flowing downward along the heat treatment apparatus group.

40. The substrate processing method according to claim 36, wherein each of the first heat treatment apparatus group and the second heat treatment apparatus group has therein a heat treatment apparatus having a movable temperature adjustment mechanism, and a heating processing mechanism that receives the processing target substrate via the temperature adjustment mechanism to heat the processing target substrate at a predetermined temperature, and a current of gas is generated inside the heat treatment apparatus to flow from the temperature adjustment mechanism side to the heating processing mechanism.

41. The substrate processing method according to claim 35, wherein in exhaust by an exhaust mechanism of the development processing apparatus and exhaust by an exhaust mechanism of the resist processing apparatus or the antireflective film processing apparatus, the gas is exhausted with an exhaust amount such that pressures inside the development processing apparatus and the resist processing apparatus or the antireflective film processing apparatus are not lower than pressures of atmosphere gases in regions the first carrying mechanism and the second carrying mechanism are disposed, respectively.

42. The substrate processing method according to claim 40, wherein a same liquid is supplied to the temperature adjustment mechanism.

43. The substrate processing method according to claim 33, wherein the gas exhausted from inside each of the processing cups and a region outside the each of the processing cups inside the resist processing apparatus or the antireflective film processing apparatus is collectively discharged outside the resist processing apparatus or the antireflective film processing apparatus, while being horizontally discharged in a region between the resist processing apparatus or the antireflective film processing apparatus and the development processing apparatus.
